(19) United States
(12) Patent Application Publication
(10) Pub. No.: US 2022/0231246 A1
(43) Pub. Date: Jul. 21, 2022

(54) PHOTOELECTRIC CONVERSION ELEMENT AND IMAGING DEVICE

(71) Applicant: SONY GROUP CORPORATION, TOKYO (JP)

(72) Inventor: YOSUKE MURAKAMI, TOKYO (JP)

(21) Appl. No.: 17/609,498

(22) PCT Filed: Apr. 14, 2020
(86) PCT No.: PCT/JP2020/016377

§ 371 Date: Nov. 8, 2021

(30) Foreign Application Priority Data
May 17, 2019 (JP) 2019-093702

(51) Int. Cl. H01L 51/44; H01L 27/30

(52) U.S. Cl. CPC H01L 51/441; H01L 27/307

(57) ABSTRACT

A photoelectric conversion element according to an embodiment of the present disclosure includes: a first electrode; a second electrode that is disposed to be opposed to the first electrode; and an organic photoelectric conversion layer that is provided between the first electrode and the second electrode and includes one organic semiconductor material. The organic photoelectric conversion layer includes at least one or more domains (D1, D2, and D3) in a horizontal cross section. The one or more domains (D1, D2, and D3) are each formed by using the one organic semiconductor material.

### TECHNICAL FIELD

The present disclosure relates to a photoelectric conversion element and an imaging device in which this is used.

### BACKGROUND ART

In recent years, devices in which organic thin films are used have been developed. One of such devices is an organic photoelectric conversion element. There has been proposed an organic thin-film solar cell, an organic imaging element, or the like in which the organic photoelectric conversion element is used. A bulk heterostructure is adopted in the organic photoelectric conversion element to increase external quantum efficiency. In the bulk heterostructure, a p-type organic semiconductor and an n-type organic semiconductor are mixed. However, the organic photoelectric conversion element has a problem that it is not possible to obtain sufficient external quantum efficiency due to a low conductive characteristic of an organic semiconductor. In addition, the organic imaging element has a problem that an electric output signal is easily delayed with respect to incident light.

In general, it has been found that molecular orientation is important for the conduction of an organic semiconductor. The same applies to an organic photoelectric conversion element having a bulk heterostructure. For this reason, in an organic photoelectric conversion element in which a conduction direction is perpendicular to a substrate, it is preferable that the organic semiconductor be oriented parallel with the substrate. In contrast, for example, PTL 1 discloses a photoelectric conversion element in which an organic semiconductor compound having horizontal orientation is used. For example, PTL 2 discloses an organic thin-film solar cell in which an orientation control layer is provided in a lower layer of an i-layer. For example, PTL 3 discloses a method of manufacturing an organic photoelectric conversion element that controls the orientation of a photoelectric conversion layer by controlling substrate temperature to form a film.

### CITATION LIST

### Patent Literature

PTL 1: Japanese Unexamined Patent Application Publication No. 2009-60053

PTL 2: Japanese Unexamined Patent Application Publication No. 2007-59457

PTL 3: Japanese Unexamined Patent Application Publication No. 2008-258421

### SUMMARY OF THE INVENTION

Incidentally, a photoelectric conversion element in which an organic semiconductor material is used is requested to have high external quantum efficiency and favorable afterimage characteristics.

It is desirable to provide a photoelectric conversion element and an imaging device each of which allows both high external quantum efficiency and favorable afterimage characteristics to be achieved.

A photoelectric conversion element according to an embodiment of the present disclosure includes: a first electrode; a second electrode that is disposed to be opposed to the first electrode; and an organic photoelectric conversion layer that is provided between the first electrode and the second electrode and includes one organic semiconductor material. The organic photoelectric conversion layer includes at least one or more domains in a horizontal cross section. The one or more domains are each formed by using the one organic semiconductor material.

An imaging device according to an embodiment of the present disclosure includes pixels each including one or more organic photoelectric conversion sections and includes the photoelectric conversion element according to the embodiment of the present disclosure described above as the organic photoelectric conversion section.

In the photoelectric conversion element according to the embodiment of the present disclosure and the imaging device according to the embodiment, the organic photoelectric conversion layer provided between the first electrode and the second electrode includes at least the one or more domains in the horizontal cross section. The one or more domains are each formed by using the one organic semiconductor material. This increases the probability that excitons generated in the organic photoelectric conversion layer irradiated with light move to the first electrode and the second electrode.

### BRIEF DESCRIPTION OF DRAWING

FIG. 1 is a schematic cross-sectional view of an example of a configuration of a photoelectric conversion element according to an embodiment of the present disclosure.

FIG. 2 is a schematic plan view of a configuration of a unit pixel of the photoelectric conversion element illustrated in FIG. 1.

FIG. 3A is a schematic diagram illustrating an example of a state of a p-type semiconductor in an organic photoelectric conversion layer illustrated in FIG. 1.

FIG. 3B is a schematic plan view of the organic photoelectric conversion layer taken along a I-I′ line illustrated in FIG. 3A.

FIG. 4 is a schematic diagram of a TEM image of the organic photoelectric conversion layer illustrated in FIG. 1.

FIG. 5 is a schematic cross-sectional view of another example of the configuration of the photoelectric conversion element according to the embodiment of the present disclosure.

FIG. 6 is a schematic cross-sectional view for describing a method of manufacturing the photoelectric conversion element illustrated in FIG. 1.

FIG. 7 is a schematic cross-sectional view illustrating a step subsequent to FIG. 6.

FIG. 8 is a schematic cross-sectional view of an example of a configuration of a photoelectric conversion element according to a modification example 1 of the present disclosure.

FIG. 9 is an equivalent circuit diagram of the photoelectric conversion element illustrated in FIG. 8.

FIG. 10 is a schematic diagram illustrating disposition of a lower electrode of the photoelectric conversion element illustrated in FIG. 8 and a transistor included in a controller.

FIG. 11 is a schematic cross-sectional view of an example of a configuration of a photoelectric conversion element according to a modification example 2 of the present disclosure.

FIG. 12 is a block diagram illustrating an overall configuration of a solid-state imaging element including the photoelectric conversion element illustrated in FIG. 1.

FIG. 13 is a functional block diagram illustrating an example of a solid-state imaging device (a camera) in which the solid-state imaging element illustrated in FIG. 12 is used.

FIG. 14 is a block diagram depicting an example of a schematic configuration of an in-vivo information acquisition system.

FIG. 15 is a view depicting an example of a schematic configuration of an endoscopic surgery system.

FIG. 16 is a block diagram depicting an example of a functional configuration of a camera head and a camera control unit (CCU).

FIG. 17 is a block diagram depicting an example of schematic configuration of a vehicle control system.

FIG. 18 is a diagram of assistance in explaining an example of installation positions of an outside-vehicle information detecting section and an imaging section.

FIG. 19 is a schematic cross-sectional view of a configuration of Experiment Example 1.

FIG. 20A is a schematic cross-sectional view describing a fabrication step of a sample for TEM analysis.

FIG. 20B is a schematic diagram illustrating a step subsequent to FIG. 20A.

FIG. 21 is a schematic diagram of a TEM image of Experiment Example 1.

FIG. 22 is a schematic diagram of a TEM image of Experiment Example 2.

FIG. 23 is a schematic diagram of a TEM image of Experiment Example 3.

FIG. 24 is a schematic diagram of a TEM image near a lower electrode of Experiment Example 1.

FIG. 25 is a schematic diagram of a TEM image near an upper electrode of Experiment Example 1.

FIG. 26A is a diagram describing a film formation method of a deposited film.

FIG. 26B is a schematic diagram illustrating a configuration of a grid and a support film illustrated in FIG. 26A.

### MODES FOR CARRYING OUT THE INVENTION

The following describes an embodiment of the present disclosure in detail with reference to the drawings. The following description is a specific example of the present disclosure, but the present disclosure is not limited to the following embodiment. In addition, the present disclosure does not limit the disposition, dimensions, dimension ratios, and the like of respective components illustrated in the diagrams thereto. It is to be noted that description is given in the following order.

1. Embodiment (An example in which an organic photoelectric conversion layer is provided that includes at least one or more domains of an organic semiconductor material in a horizontal cross section)

### 1-1. Configuration of Photoelectric Conversion Element

### 1-2. Method of Manufacturing Photoelectric Conversion Element

### 1-3. Workings and Effects

### 2. Modification Examples

2-1. Modification Example 1 (An example of a photoelectric conversion element in which a lower electrode includes a plurality of electrodes)
2-2. Modification Example 2 (An example of a photoelectric conversion element in which a plurality of organic photoelectric conversion sections is stacked)

### 3. Application Examples

### 4. Practical Application Examples

### 5. Working Examples

### 1. EMBODIMENT

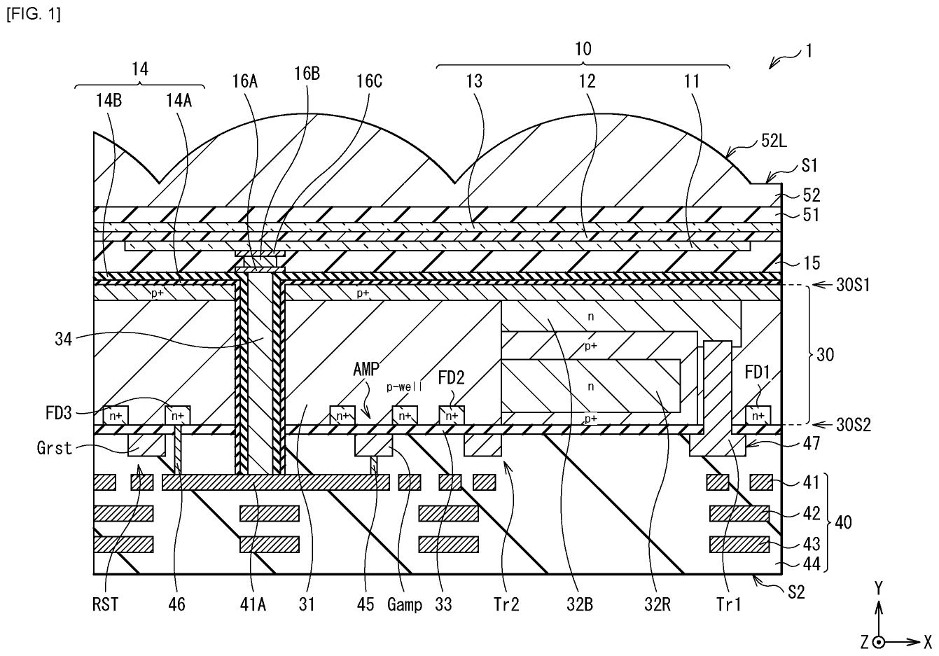

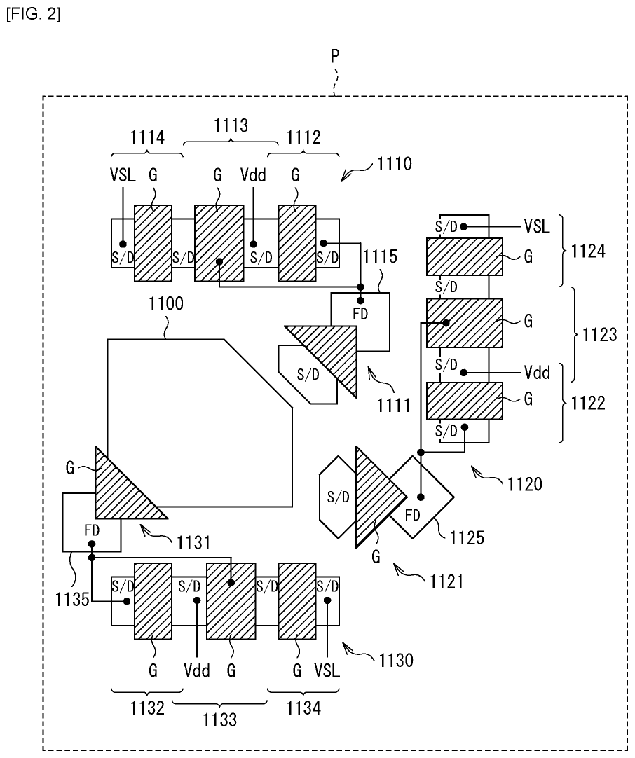

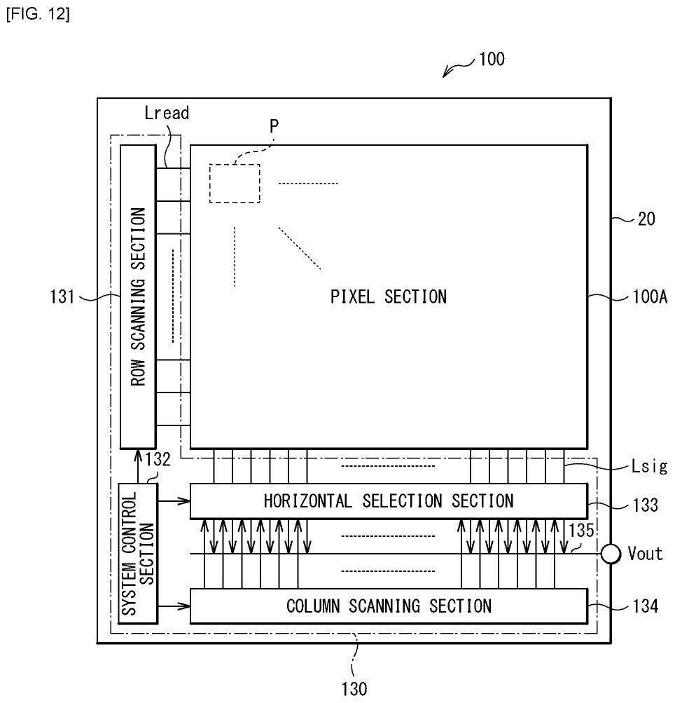

FIG. 1 illustrates an example of a cross-sectional configuration of a photoelectric conversion element (a photoelectric conversion element 1) according to an embodiment of the present disclosure. FIG. 2 illustrates an example of a planar configuration of the photoelectric conversion element 1 illustrated in FIG. 1. The photoelectric conversion element 1 is included, for example, in one pixel (a unit pixel P) in a solid-state imaging device (an imaging device 100) such as a back-illuminated (back light receiving) CCD (Charge Coupled Device) image sensor or CMOS (Complementary Metal Oxide Semiconductor) image sensor (see FIG. 12). The photoelectric conversion element 1 is of a so-called vertical spectroscopic type in which one organic photoelectric conversion section 10 and two inorganic photoelectric conversion sections 32B and 32R are stacked in the vertical direction. The organic photoelectric conversion section 10 and the two inorganic photoelectric conversion sections 32B and 32R each selectively detect respective pieces of light in different wavelength regions to perform photoelectric conversion. The present embodiment adopts a configuration in which an organic photoelectric conversion layer 12 included in the organic photoelectric conversion section 10 includes one or more domains in a horizontal cross section. Each of the one or more domains is formed by using an organic semiconductor material (one organic semiconductor material).

### 1-1. Configuration of Photoelectric Conversion Element

In the photoelectric conversion element 1, one organic photoelectric conversion section 10, and two inorganic photoelectric conversion sections 32B and 32R are stacked in the vertical direction for each unit pixel P. The organic photoelectric conversion section 10 is provided on a back surface (a first surface 30S1) side of a semiconductor substrate 30. The inorganic photoelectric conversion sections 32B and 32R are formed to be embedded in the semiconductor substrate 30 and stacked in the thickness direction of the semiconductor substrate 30. The organic photoelectric conversion section 10 includes the organic photoelectric conversion layer 12 including a p-type semiconductor and an n-type semiconductor and having a bulk hetero junction structure in a layer. The bulk hetero junction structure is a p/n junction surface formed by mixture of a p-type semiconductor and an n-type semiconductor.

The organic photoelectric conversion section 10 and the inorganic photoelectric conversion sections 32B and 32R perform photoelectric conversion by selectively detecting respective pieces of light in different wavelength bands. Specifically, the organic photoelectric conversion section 10 acquires a green (G) color signal. The inorganic photoelectric conversion sections 32B and 32R respectively acquire a blue (B) color signal and a red (R) color signal by using a difference between absorption coefficients. This allows the photoelectric conversion element 1 to acquire a plurality types of color signals in one pixel without using a color filter.

It is to be noted that, in the present embodiment, description is given of a case of reading electron as signal charge (a case where the n-type semiconductor region is used as a photoelectric conversion layer) of a pair of the electrons and holes generated from photoelectric conversion. In addition, in the drawings, “+ (plus)” assigned to “p” and “n” indicates that the concentration of p-type or n-type impurities is high and “++” indicates that the concentration of p-type or n-type impurities is further higher than “+”.

The semiconductor substrate 30 includes, for example, an n-type silicon (Si) substrate and has a p-well 31 in a predetermined region. A second surface (the front surface of the semiconductor substrate 30) 30S2 of the p-well 31 is provided, for example, with various floating diffusions (floating diffusion layers) FD (e.g., FD1, FD2, and FD3), various transistors Tr (e.g., a vertical transistor (a transfer transistor) Tr1, a transfer transistor Tr2, an amplifier transistor (a modulation element) AMP, and a reset transistor RST), and a multilayer wiring line 40. The multilayer wiring line 40 has a configuration in which wiring layers 41, 42, and 43, for example, are stacked in an insulating layer 44. In addition, a peripheral portion of the semiconductor substrate 30 is provided with a peripheral circuit (not illustrated) including a logic circuit or the like.

It is to be noted that FIG. 1 illustrates the first surface 30S1 side of the semiconductor substrate 30 as a light incident surface S1 and the second surface 30S2 side thereof as a wiring layer side S2.

The inorganic photoelectric conversion sections 32B and 32R each include, for example, a PIN (Positive Intrinsic Negative) type photodiode and each have a p-n junction in a predetermined region of the semiconductor substrate 30. The inorganic photoelectric conversion sections 32B and 32R allow light to be dispersed in the vertical direction by using the wavelength bands of absorbed light that are different in accordance with the incidence depth on the silicon substrate.

The inorganic photoelectric conversion section 32B selectively detects the blue light to accumulate the signal charge corresponding to blue and is installed at a depth that allows the blue light to be photoelectrically converted efficiently. The inorganic photoelectric conversion section 32R selectively detects the red light to accumulate the signal charge corresponding to red and is installed at a depth that allows the red light to be photoelectrically converted efficiently. It is to be noted that blue (B) is a color corresponding to a wavelength band of 450 nm to 495 nm, for example, and red (R) is a color corresponding to a wavelength band of 620 nm to 750 nm, for example. It is sufficient if the inorganic photoelectric conversion sections 32B and 32R are able to detect pieces of light of a portion or all of the respective wavelength bands.

Specifically, as illustrated in FIG. 1, the inorganic photoelectric conversion section 32B and the inorganic photoelectric conversion section 32R each include, for example, a p+ region serving as a hole accumulation layer and an n region serving as an electron accumulation layer (they each have a p-n-p stacked structure). Then region of the inorganic photoelectric conversion section 32B is coupled to the vertical transistor Tr1. The p+ region of the inorganic photoelectric conversion section 32B bends along the vertical transistor Tr 1 and links to the p+ region of the inorganic photoelectric conversion section 32R.

As described above, the second surface 30S2 of the semiconductor substrate 30 is provided, for example, with the floating diffusions (floating diffusion layers) FD1, FD2, and FD3, the vertical transistor (the transfer transistor) Tr1, the transfer transistor Tr2, the amplifier transistor (the modulation element) AMP, and the reset transistor RST.

The vertical transistor Tr1 is a transfer transistor that transfers, to the floating diffusion FD1, the signal charge (electrons, here) generated and accumulated in the inorganic photoelectric conversion section 32B. The signal charge corresponds to blue. The inorganic photoelectric conversion section 32B is formed at a deep position from the second surface 30S2 of the semiconductor substrate 30 and it is thus preferable that the transfer transistor of the inorganic photoelectric conversion section 32B include the vertical transistor Tr1.

The transfer transistor Tr2 transfers, to the floating diffusion FD2, the signal charge (electrons, here) generated and accumulated in the inorganic photoelectric conversion section 32R. The signal charge corresponds to red. The transfer transistor Tr2 includes, for example, a MOS transistor.

The amplifier transistor AMP is a modulation element that modulates, into a voltage, the amount of electric charge generated in the organic photoelectric conversion section 10 and includes, for example, a MOS transistor.

The reset transistor RST resets the electric charge transferred from the organic photoelectric conversion section 10 to the floating diffusion FD3 and includes, for example, a MOS transistor.

A lower first contact 45, a lower second contact 46, and an upper contact 16B each include, for example, a doped silicon material such as PDAS (Phosphorus Doped Amorphous Silicon) or a metal material such as aluminum (Al), tungsten (W), titanium (Ti), cobalt (Co), hafnium (Hf), or tantalum (Ta).

The organic photoelectric conversion section 10 is provided on the first surface 30S1 side of the semiconductor substrate 30. The organic photoelectric conversion section 10 has a configuration in which, for example, a lower electrode 11, the organic photoelectric conversion layer 12, and an upper electrode 13 are stacked in this order from the side of the first surface 30S1 of the semiconductor substrate 30. The lower electrode 11 is, for example, separately formed for each of the photoelectric conversion elements 1. The organic photoelectric conversion layer 12 and the upper electrode 13 are provided as continuous layers common to the plurality of photoelectric conversion elements 1.

Between the first surface 30S1 of the semiconductor substrate 30 and the lower electrode 11, for example, inter-layer insulating layers 14 and 15 are stacked in this order from the semiconductor substrate 30 side. The inter-layer insulating layer 14 has a configuration in which, for example, a layer (a fixed electric charge layer) 14A having fixed electric charge and a dielectric layer 14B having insulation properties are stacked. There is provided a protective layer 51 on the upper electrode 13. An on-chip lens layer 52 included in an on-chip lens 52L and also serving as a planarization layer is disposed above the protective layer 51.

There is provided a through electrode 34 between the first surface 30S1 and the second surface 30S2 of the semiconductor substrate 30. The organic photoelectric conversion section 10 is coupled to a gate Gamp of the amplifier transistor AMP and the floating diffusion FD3 through this through electrode 34. This allows the photoelectric conversion element 1 to transfer electric charge generated in the organic photoelectric conversion section 10 on the first surface 30S1 side of the semiconductor substrate 30 to the second surface 30S2 side of the semiconductor substrate 30 through the through electrode 34 in a favorable manner, thus making it possible to increase the characteristics.

The through electrode 34 is provided, for example, for each organic photoelectric conversion section 10 of the photoelectric conversion element 1. The through electrode 34 has a function of a connector for the organic photoelectric conversion section 10 and the gate Gamp of the amplifier transistor AMP and the floating diffusion FD3 and serves as a transmission path for electric charge generated in the organic photoelectric conversion section 10.

The lower end of the through electrode 34 is coupled, for example, to a coupling section 41A in the wiring layer 41 and the coupling section 41A and the gate Gamp of the amplifier transistor AMP are coupled through the lower first contact 45. The coupling section 41A and the floating diffusion FD3 are coupled to the lower electrode 11 through the lower second contact 46. It is to be noted that FIG. 1 illustrates the through electrode 34 in the shape of a cylinder, but this is not limitative. The through electrode 34 may have a tapered shape, for example.

As illustrated in FIG. 1, it is preferable that a reset gate Grst of the reset transistor RST be disposed next to the floating diffusion FD3. This makes it possible to cause the reset transistor RST to reset the electric charge accumulated in the floating diffusion FD3.

In the photoelectric conversion element 1 according to the present embodiment, light inputted to the organic photoelectric conversion section 10 from the upper electrode 13 side is absorbed by the organic photoelectric conversion layer 12. Excitons generated by this move to an interface between an electron donor and an electron acceptor included in the organic photoelectric conversion layer 12 and undergo exciton separation, that is, dissociate into electrons and holes. The electric charge (electrons and holes) generated here is transported to different electrodes by diffusion due to a difference in carrier concentration or by an internal electric field due to a difference in work functions between an anode (here, the upper electrode 13) and a cathode (here, the lower electrode 11) and is detected as a photocurrent. In addition, the application of an electric potential between the lower electrode 11 and the upper electrode 13 makes it possible to control directions in which electrons and holes are transported.

The following describes configurations, materials, or the like of respective sections.

The organic photoelectric conversion section 10 is an organic photoelectric conversion element that absorbs the green light corresponding to a portion or all of selective wavelength bands (e.g., 400 nm or more and 700 nm or less) to generate an electron-hole pair.

The lower electrode 11 is provided in a region that directly faces light receiving surfaces of the inorganic photoelectric conversion sections 32B and 32R formed in the semiconductor substrate 30 and covers these light receiving surfaces. The lower electrode 11 includes an electrically conducive layer having light transmissivity and includes, for example, ITO (indium-tin oxide). However, as a material included in the lower electrode 11, a tin oxide (SnO₂)-based material obtained by adding a dopant or a zinc oxide-based material formed by adding a dopant to aluminum zinc oxide (ZnO) may be used in addition to this ITO. Examples of the zinc oxide-based materials include aluminum zinc oxide (AZO) obtained by adding aluminum (Al) as the dopant, gallium (Ga)-added gallium zinc oxide (GZO), and indium (In)-added indium zinc oxide (IZO). In addition, CuI, InSbO₄, ZnMgO, CuInO₂, MglN₂O₄, CdO, ZnSnO₃, or the like may also be used in addition to these.

The organic photoelectric conversion layer 12 converts optical energy to electric energy. The organic photoelectric conversion layer 12 includes, for example, two or more types of organic semiconductor materials and includes, for example, one or both of p-type semiconductors and n-type semiconductors. In a case where the organic photoelectric conversion layer 12 includes the two types of organic semiconductor materials including p-type semiconductors and n-type semiconductors, for example, it is preferable one of the p-type semiconductors and the n-type semiconductors be materials having transmissivity to visible light and the other thereof be materials that photoelectrically convert light in a selective wavelength region (e.g., 450 nm or more and 650 nm or less). Alternatively, the organic photoelectric conversion layer 12 includes, for example, three types of organic semiconductor materials including materials (light absorbers), n-type semiconductors, and p-type semiconductors. The materials (the light absorbers) photoelectrically convert light in a selective wavelength region. The n-type semiconductors and the p-type semiconductors each have light transmissivity to visible light. The organic photoelectric conversion layer 12 has a bulk heterostructure in which the plurality of these organic semiconductor materials is randomly mixed in the layer.

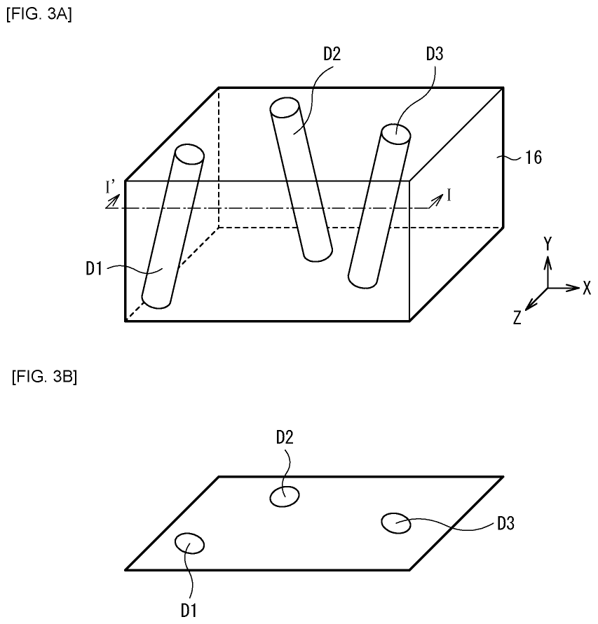

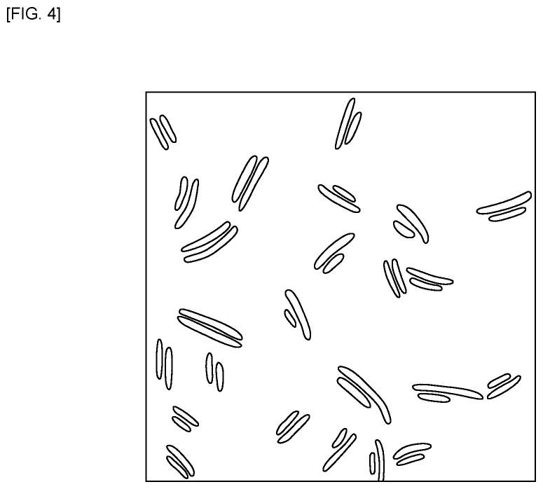

In the organic photoelectric conversion layer 12, two types (p-type semiconductors and n-type semiconductors) or three types (light absorbers, p-type semiconductors, and n-type semiconductors) of organic semiconductor materials each form a plurality of grains and randomly mixed as described above. The present embodiment adopts a configuration in which a portion of at least one type of organic semiconductor materials among the plurality of types of organic semiconductor materials described above forms a plurality of domains in the layer and at least one or more domains are confirmed in a horizontal cross section of the organic photoelectric conversion layer 12. The following describes this in detail with reference to FIGS. 3A, 3B, and 4. It is to be noted that the domain is a region including a continuous arrangement of one type of the organic semiconductor materials described above. Each of the organic semiconductor materials described above may form a domain in the organic photoelectric conversion layer 12. In addition, a domain may include two or more types of organic semiconductor materials.

FIG. 3A schematically illustrates an example of the state of one organic semiconductor material (e.g., p-type semiconductors) in the organic photoelectric conversion layer 12 according to the present embodiment. In the organic photoelectric conversion layer 12, as illustrated in FIG. 3A, a plurality of domains is formed that each includes a p-type semiconductor. It is to be noted that FIG. 3A illustrates, as an example, a case where three domains D1, D2, and D3 are formed. FIG. 3B schematically illustrates a planar structure of the organic photoelectric conversion layer 12 taken along a I-I′ line illustrated in FIG. 3A. It is preferable that it is possible to confirm substantially the same number of domains in horizontal cross sections of the organic photoelectric conversion layer 12 according to the present embodiment at any positions in the Y axis direction. In other words, it is preferable that the organic photoelectric conversion layer 12 have substantially the same areal density of domains at any positions in the film thickness direction (the Y axis direction). Electric charge (electrons and holes) that has undergone exciton separation in the domains moves to the lower electrode 11 and the upper electrode 13 through the domains. Substantially the same areal density of domains at any positions in the organic photoelectric conversion layer 12 in the film thickness direction (the Y axis direction) as described above therefore increases the probability that electric charge moves to the electrodes and makes it possible to obtain high external quantum efficiency and favorable afterimage characteristics.

It is to be noted that it is possible to confirm the areal density of domains in the organic photoelectric conversion layer 12 by using a transmission electron microscope (Transmission Electron Microscope; TEM). This is described in detail below. For example, in a case where the number (N) of domains is measured in an area of 100 nm×100 nm observed by TEM, it is possible to predict that the number of domains is substantially the same in planes taken along any positions as long as the front surface side and the substrate side have the same number of domains within an error of ±√N (the square root of N) that is a so-called statistical error. To increase the collection efficiency of electric charge, it is desirable that the domain density be equal to the number N of domains measured in unit area within the error corresponding to the double of the square root of the number N of domains. It is thus assumed that, in a case where the organic photoelectric conversion layer 12 has substantially the same areal density of domains at any positions in the film thickness direction, the areal density falls within the range of ±√N.

In addition, it is preferable that the areal density (the number of domains/unit area parallel with the substrate surface of the semiconductor substrate 30) of domains in the organic photoelectric conversion layer 12 be 1500 domains/square micron or more. Further, it is preferable that the areal density (the number of domains/unit area parallel with the substrate surface of the semiconductor substrate 30) of domains in the organic photoelectric conversion layer 12 be 2500 domains/square micron or more. 2500 domains/square micron corresponds to a density of one domain in square area having a side of 20 nm. Increasing the areal density of domains in the organic photoelectric conversion layer 12 in this way increases the probability that excitons generated in the organic photoelectric conversion layer 12 irradiated with light reach the domains and makes it possible to further increase the probability that electric charge moves to an electrode.

Further, it is preferable that each of a plurality of domains have a percolation structure in which the domain vertically extends through the organic photoelectric conversion layer 12 in the film thickness direction (the Y axis direction), for example, as illustrated in FIG. 3B. Further, it is preferable that at least some domains among the plurality of domains partially (e.g., ends of domains each having a percolation structure) be in contact with one or both of the lower electrode 11 and the upper electrode 13. This increases the probability that electric charge (electrons and holes) moves from the domains to the lower electrode 11 or the upper electrode 13.

Still further, it is preferable that at least a portion of a plurality of domains have crystallizability. Specifically, it is preferable that at least a portion of a plurality of domains include a crystal. Each of the plurality of domains includes a crystal. This makes it possible to reduce electric charge trapping in the domains.

In addition, in a case of the same areal density of domains in the organic photoelectric conversion layer 12, it is more advantageous that crystals included in the domains are larger in terms of the movement efficiency of electric charge. In contrast, this may possibly decrease regions that absorb light to generate excitons. It is therefore desirable that the planar projected area ratio, for example, obtained by projecting the organic photoelectric conversion layer 12 in the film thickness direction be 0.5 or less as the size of crystals included in a plurality of domains formed in the organic photoelectric conversion layer 12. This makes it possible to increase the movement efficiency of electric charge while maintaining the generation of excitons necessary for photoelectric conversion.

The internal structure of the organic photoelectric conversion layer 12 is confirmable, for example, by using TEM as described above. The TEM is a device that two-dimensionally projects a three-dimensional object to shoot a so-called TEM image. The TEM allows the shape of a crystal having about several nanometers to be grasped.

A crystal generally refers to a three-dimensional structure in which atoms or molecules are regularly arranged. Electrons scatter while passing through crystals and interfere due to the electronic waves. As a result, the electrons are strengthened or weakened in a specific direction. In a case where electrons pass through a periodic structure called crystal planes in substantially parallel directions, interference fringes are observed in a TEM image. The interference fringes are referred to as lattice fringes in general. Here, the TEM image thereof is referred to as lattice image.

A condition under which a lattice image is observed depends on a device. A defocus amount (a defocus amount) is, however, observed near so-called Scherzer focus in many cases. For example, it is calculated in accordance with Expression (1) below. At the Scherzer focus, the diffracted waves are shifted with respect to the transmitted waves by about ¼ wavelength to form an image. This forms contrast suitable to associate the lattice image and the atomic arrangement. In addition, the intervals (the period) of lattice fringes correspond to the period of crystal planes. In a case where the lattice image further goes out of focus, the lattice image has black and white inverted therein. Further, the contour around the crystals becomes remarkable, for example. The image exhibits varying aspects. In addition, the aspect depends on the accelerating voltage (the wavelength of electrons) of TEM, the aberration of a lens, the size of the crystals, and the like.

(Math. 1)

Scherzer focus=1.2√(Cs·λ) Expression (1)

(Cs represents a spherical aberration coefficient and λ represents the wavelength of electrons)

Even in a case where a crystal plane is not parallel with the electron transmission direction, a fringe (so-called fringe contrast) is formed near the contour of a scatterer (e.g., a crystal) different in density in the sample by shifting the focus. In general, interference fringes corresponding to about several atomic columns or molecular columns are frequently observed at the Scherzer focus. A defocus amount of about several μm tends to relatively strengthen fringe contrast.

The defocus amount is sometimes shifted by about several μm by proactively using this phenomenon to observe a scatterer that is difficult to contrast. This is sometimes referred to as defocus image, but the Scherzer focus is also a defocus image (a defocus amount different in scale) in strict terms.

In general, a sample that is analyzed by TEM has a thickness of about several tens of nm in the electron transmission direction. This is because electrons and a substance have a strong interaction and only a thin sample allows electrons to pass through the sample. However, there are examples of several nm for nano-carbon and several hundreds of nm to μm for observation using an ultra-high voltage electron microscope. In general, it is determined that the defocus amount is zero in a case where the contrast is the weakest. A lattice image is shot by defocusing from that by the Scherzer focus. The defocus amount, however, depends on the position of the sample in the electron transmission direction. It is thus a portion of the sample that satisfies the Scherzer focus condition.

Meanwhile, in a case of a defocus amount of about several μm, the defocus amount is much greater than the thickness of the sample. As a result, the contour of the scatterer such as a crystal is observed as substantially similar fringe contrast in spite of different positions in the electron transmission direction.

As described above, the present embodiment defines a domain as a crystal in a case where a periodic fringe pattern is observed in a portion of domains in an image (a TEM image) of domains shot under the defocus condition under which the focus of the TEM is shifted by 1 μm or more. Here, the wording “a portion of domains” is used because of the principled reason that a crystal plane is not necessarily parallel with the transmission direction of electrons and a fringe pattern is thus observed in only a portion of the crystals.

FIG. 4 schematically illustrates a portion (a square having a side of 100 nm) of a TEM image of the organic photoelectric conversion layer 12 (Experiment Example 1 described below) shot under the defocus condition described above. The organic photoelectric conversion layer 12 is fabricated by using p-type semiconductors that form the domains as described above. In the organic photoelectric conversion layer 12 according to the present embodiment, as illustrated in FIG. 4, lattice fringes including two or more lines are confirmable.

As described above, it is preferable that the organic photoelectric conversion layer 12 include two types of organic semiconductor materials including n-type semiconductors and p-type semiconductors or three types of organic semiconductor materials including light absorbers, n-type semiconductors, and p-type semiconductors. There is a junction surface (a p/n junction surface) between the p-type semiconductors and the n-type semiconductors in the layer. Each of the light absorbers has the maximal absorption wavelength within a range of, for example, 450 nm or more and 650 nm or less. Examples of the light absorbers include subphthalocyanine or a derivative thereof. Each of the p-type semiconductors relatively functions as an electron donor (a donor) and the use of a material having a hole transporting property is preferable, for example. Examples of such a material include a compound including acene or thienoacene as the mother skeleton and including a phenyl group, a biphenyl group, a terphenyl group, or a naphthyl group as the side chain or the substituent thereof in addition to 3,6-BP-BBTN (see Expression 1) used in a working example 1. Each of the n-type semiconductors relatively functions as an electron acceptor (acceptor) and the use of a material having an electron transporting property is preferable, for example. Examples of the n-type semiconductors include fullerene C60 or a derivative thereof. The thickness of the organic photoelectric conversion layer 12 is, for example, 50 nm to 500 nm. It is preferable that the interface between the organic photoelectric conversion layer 12 and the upper electrode 13 have a surface roughness of 10 nm or less.

It is to be noted that an example in which p-type semiconductors form a plurality of domains has been described in the present embodiment, but this is not limitative. For example, n-type semiconductors may form a plurality of domains.

The upper electrode 13 includes an electrically conductive film having light transmissivity similar to that of the lower electrode 11. In the imaging device 100 in which the photoelectric conversion element 1 is used as one pixel, this upper electrode 13 may be separated for each of the pixels or may be formed as an electrode common to the respective pixels. The thickness of the upper electrode 13 is, for example, 10 nm to 200 nm.

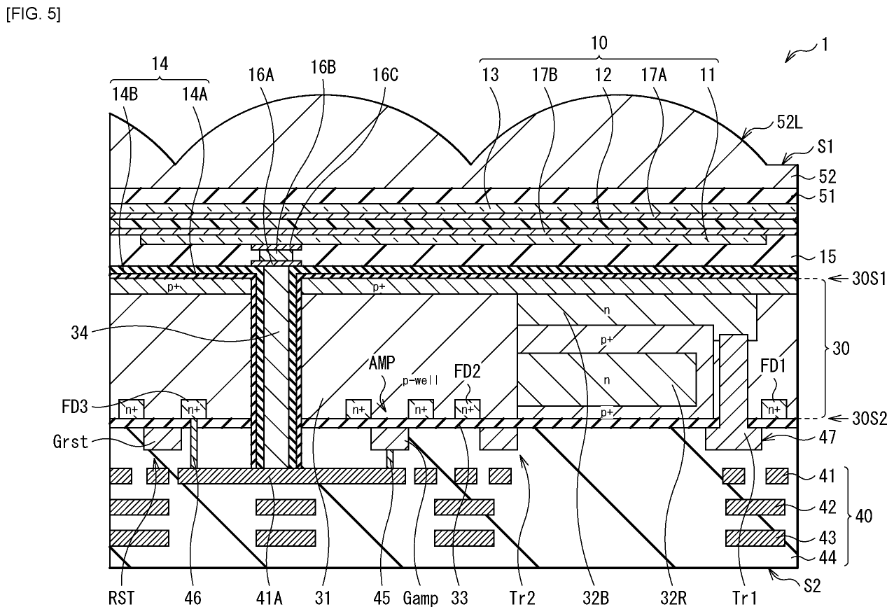

It is to be noted that there may be provided other layers between the organic photoelectric conversion layer 12 and the lower electrode 11 and between the organic photoelectric conversion layer 12 and the upper electrode 13. FIG. 5 illustrates another example of the cross-sectional configuration of the photoelectric conversion element 1 according to the present embodiment. Buffer layers 17A and 17B may be provided between the organic photoelectric conversion layer 12 and the lower electrode 11 or between the organic photoelectric conversion layer 12 and the upper electrode 13. Alternatively, the buffer layers 17A and 17B may be provided both between the organic photoelectric conversion layer 12 and the lower electrode 11 and between the organic photoelectric conversion layer 12 and the upper electrode 13. In addition, for example, an underlying film, a hole transport layer, an electron blocking film, the organic photoelectric conversion layer 12, a hole blocking film, an electron transport layer, a work function adjusting film, and the like may be stacked in order from the lower electrode 11 side.

The fixed electric charge layer 14A may be a film having positive fixed electric charge or a film having negative fixed electric charge. As a material of the film having negative fixed electric charge, hafnium oxide, aluminum oxide, zirconium oxide, tantalum oxide, titanium oxide, and the like are included. In addition, as a material other than the materials described, lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, an aluminum oxynitride film, or the like may be used.

The fixed electric charge layer 14A may also have a configuration in which two or more types of films are stacked. This makes it possible to further increase a function of a hole accumulation layer in a case of a film having negative fixed electric charge, for example.

Although a material of the dielectric layer 14B is not limited in particular, the dielectric layer 14B includes, for example, a silicon oxide film, TEOS, a silicon nitride film, a silicon oxynitride film, or the like.

The inter-layer insulating layer 15 includes, for example, a single-layer film including one type of silicon oxide, silicon nitride, silicon oxynitride (SiON), and the like or a stacked film including two or more types thereof.

The protective layer 51 includes a material having light transmissivity and includes, for example, a single layer film including any of silicon oxide, silicon nitride, silicon oxynitride, and the like or a stacked film including two or more types thereof. The thickness of the protective layer 51 is, for example, 100 nm to 30000 nm.

The on-chip lens layer 52 is formed on the protective layer 51 to cover the whole surface thereof. The plurality of on-chip lenses (the microlenses) 52L is provided on the front surface of the on-chip lens layer 52. The on-chip lenses 52L condense light inputted from above the on-chip lens 52L on the respective light receiving surfaces of the organic photoelectric conversion section 10 and the inorganic photoelectric conversion sections 32B and 32R. In the present embodiment, the multilayer wiring line 40 is formed on the second surface 30S2 side of the semiconductor substrate 30. This allows the respective light receiving surfaces of the organic photoelectric conversion section 10 and the inorganic photoelectric conversion sections 32B and 32R to be disposed close to each other, thus making it possible to reduce sensitivity variations between the respective colors generated depending on the F-value of the on-chip lens 52L.

It is possible in the photoelectric conversion element 1 according to the present embodiment to configure the organic photoelectric conversion section 10 and the inorganic photoelectric conversion sections 32B and 32R, for example, as illustrated in FIG. 2. FIG. 2 illustrates an example of a planar configuration of each of the unit pixels P included in a pixel section 100A, for example, illustrated in FIG. 12.

The unit pixel P includes a photoelectric conversion region 1100 in which a red photoelectric conversion section (the inorganic photoelectric conversion section 32R in FIG. 1), a blue photoelectric conversion section (the inorganic photoelectric conversion section 32B in FIG. 1), and a green photoelectric conversion section (the organic photoelectric conversion section 10 in FIG. 1) (neither of which is illustrated in FIG. 2) that photoelectrically convert respective pieces of light in the wavelengths of R (Red), G (Green), and B (Blue) are stacked in three layers in the order of the green photoelectric conversion section, the blue photoelectric conversion section, and the red photoelectric conversion section, for example, from the light receiving surface (the light incident surface Si in FIG. 1) side. Further, the unit pixel P includes a Tr group 1110, a Tr group 1120, and a Tr group 1130 as electric charge readout sections that read electric charge corresponding to the respective pieces of light in wavelengths of R, G, and B from the red photoelectric conversion section, the green photoelectric conversion section, and the blue photoelectric conversion section. The imaging device 100 disperses light in the vertical direction in one unit pixel P. In other words, the imaging device 100 disperses the respective pieces of light of R, G, and B in the respective layers serving as the red photoelectric conversion section, the green photoelectric conversion section, and the blue photoelectric conversion section stacked in the photoelectric conversion region 1100.

The Tr group 1110, the Tr group 1120, and the Tr group 1130 are formed on the periphery of the photoelectric conversion region 1100. The Tr group 1110 outputs, as a pixel signal, the signal charge corresponding to the light of R generated and accumulated in the red photoelectric conversion section. The Tr group 1110 includes a transfer Tr (MOS FET) 1111, a reset Tr 1112, an amplification Tr 1113, and a selection Tr 1114. The Tr group 1120 outputs, as a pixel signal, the signal charge corresponding to the light of B generated and accumulated in the blue photoelectric conversion section. The Tr group 1120 includes a transfer Tr 1121, a reset Tr 1122, an amplification Tr 1123, and a selection Tr 1124. The Tr group 1130 outputs, as a pixel signal, the signal charge corresponding to the light of G generated and accumulated in the green photoelectric conversion section. The Tr group 1130 includes a transfer Tr 1131, a reset Tr 1132, an amplification Tr 1133, and a selection Tr 1134.

The transfer Tr 1111 includes (a source/drain region serving as) a gate G, a source/drain region S/D, and FD (a floating diffusion) 1115. The transfer Tr 1121 includes a gate G, a source/drain region S/D, and FD 1125. The transfer Tr 1131 includes a gate G, (a source/drain region S/D coupled to) the green photoelectric conversion section of the photoelectric conversion region 1100, and FD 1135. It is to be noted that the source/drain region of the transfer Tr 1111 is coupled to the red photoelectric conversion section of the photoelectric conversion region 1100 and the source/drain region S/D of the transfer Tr 1121 is coupled to the blue photoelectric conversion section of the photoelectric conversion region 1100.

The reset Trs 1112, 1132, and 1122, the amplification Trs 1113, 1133, and 1123, and the selection Trs 1114, 1134, and 1124 each include a gate G and a pair of source/drain regions S/D disposed across the gate G.

The FDs 1115, 1135, and 1125 are coupled to the respective source/drain regions S/D serving as sources of the reset Trs 1112, 1132, and 1122, and are coupled to the respective gates G of the amplification Trs 1113, 1133 and 1123. A power supply Vdd is coupled to the common source/drain region S/D in each of the reset Tr 1112 and the amplification Tr 1113, the reset Tr 1132 and the amplification Tr 1133, and the reset Tr 1122 and the amplification Tr 1123. VSL (a vertical signal line) is coupled to each of the source/drain regions S/D serving as the respective sources of the selection Trs 1114, 1134, and 1124.

The technology according to the present disclosure is applicable to the photoelectric conversion element as described above.

### 1-2. Method of Manufacturing Photoelectric Conversion Element

It is possible to manufacture the photoelectric conversion element 1 according to the present embodiment, for example, as follows.

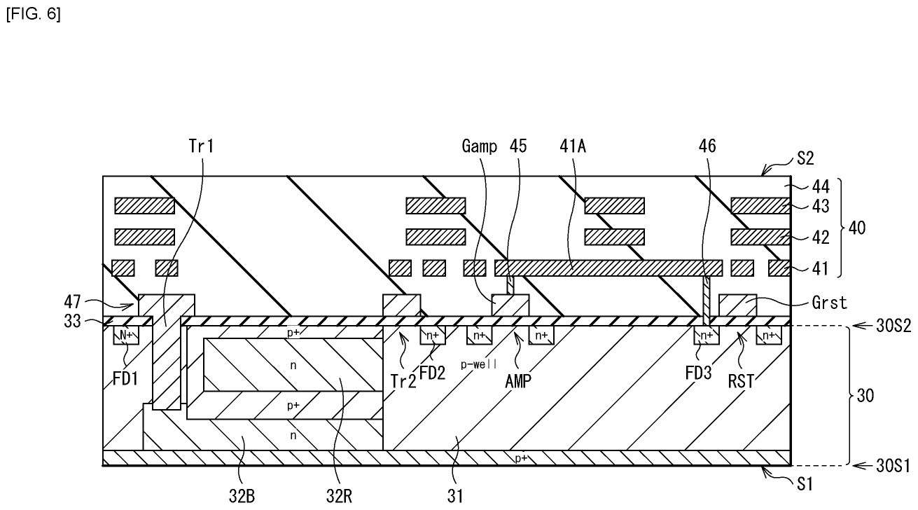

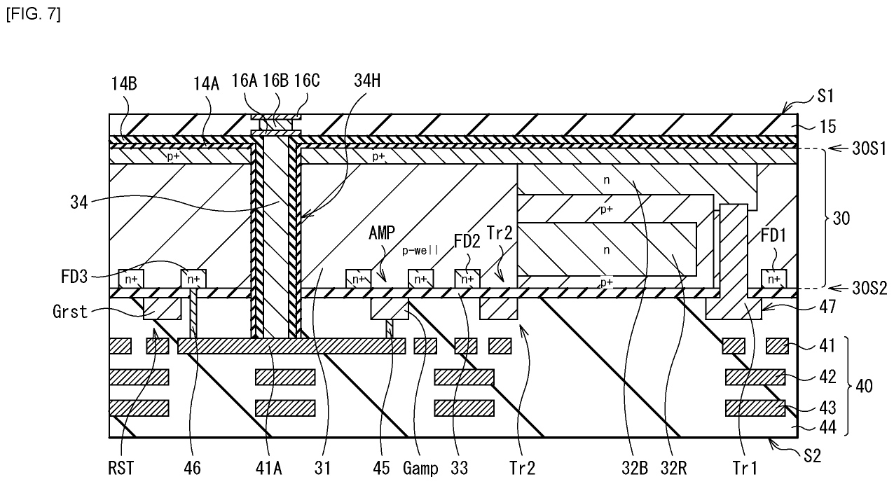

FIGS. 6 and 7 illustrate a method of manufacturing the photoelectric conversion element 1 in order of steps. First, as illustrated in FIG. 6, the p-well 31, for example, is formed as a first electrical conduction type of well in the semiconductor substrate 30. The second electrical conduction type (e.g., n-type) of inorganic photoelectric conversion sections 32B and 32R are formed in this p-well 31. A p+ region is formed near the first surface 30S1 of the semiconductor substrate 30.

As also illustrated in FIG. 6, on the second surface 30S2 of the semiconductor substrate 30, after n+ regions serving as the floating diffusions FD1 to FD3 are formed, a gate insulating layer 62 and a gate wiring layer 47 including the respective gates of the vertical transistor Tr1, the transfer transistor Tr2, the amplifier transistor AMP, and the reset transistor RST are formed. This forms the vertical transistor Tr1, the transfer transistor Tr2, the amplifier transistor AMP, and the reset transistor RST. Further, the multilayer wiring line 40 is formed on the second surface 30S2 of the semiconductor substrate 30. The multilayer wiring line 40 includes wiring layers 41 to 73 and the insulating layer 44. The wiring layers 41 to 73 include the lower first contact 45, the lower second contact 46, and the coupling section 41A.

As a base of the semiconductor substrate 30, for example, an SOI (Silicon on Insulator) substrate is used in which the semiconductor substrate 30, an embedded oxide film (not illustrated), and a holding substrate (not illustrated) are stacked. Although not illustrated in FIG. 6, the embedded oxide film and the holding substrate are joined to the first substrate surface 30S1 of the semiconductor substrate 30. After ion implantation, an annealing process is performed.

Then, a support substrate (not illustrated), another semiconductor substrate, or the like is joined to the second surface 30S2 side (the multilayer wiring line 40 side) of the semiconductor substrate 30 and flipped vertically. Subsequently, the semiconductor substrate 30 is separated from the embedded oxide film and the holding substrate of the SOI substrate to expose the first surface 30S1 of the semiconductor substrate 30. It is possible to perform these steps with technology used in a normal CMOS process such as ion implantation and CVD (Chemical Vapor Deposition).

Subsequently, as illustrated in FIG. 7, the semiconductor substrate 30 is processed from the first surface 30S1 side by dry etching, for example, to form an annular opening 34H. The opening 34H has a depth penetrating from the first surface 30S1 to the second surface 30S2 of the semiconductor substrate 30 as illustrated in FIG. 7 and reaching, for example, the coupling section 41A.

Subsequently, as illustrated in FIG. 7, for example, the negative fixed electric charge layer 14A is formed on the first surface 30S1 of the semiconductor substrate 30 and the side surface of the opening 34H. Two or more types of films may be stacked as the negative fixed electric charge layer 14A. This makes it possible to further increase a function of the hole accumulation layer. The dielectric layer 14B is formed after the negative fixed electric charge layer 14A is formed.

Next, an electric conductor is embedded in the opening 34H to form the through electrode 34. As the electric conductor, for example, a metal material such as aluminum (Al), tungsten (W), titanium (Ti), cobalt (Co), hafnium (Hf), and tantalum (Ta) is usable in addition to a doped silicon material such as PDAS (Phosphorus Doped Amorphous Silicon).

Subsequently, after a pad section 16A is formed on the through electrode 34, the inter-layer insulating layer 15 is formed on the dielectric layer 14B and the pad section 16A. In the inter-layer insulating layer 15, the upper contact 16B and a pad section 16C are provided on the pad section 16A. The upper contact 16B and the pad section 16C electrically couple the lower electrode 11 and the through electrode 34 (specifically, the pad section 16A on the through electrode 34).

Next, the lower electrode 11, the organic photoelectric conversion layer 12, the upper electrode 13, and the protective layer 51 are formed in this order on the inter-layer insulating layer 15. As the organic photoelectric conversion layer 12, for example, films of the three types of organic semiconductor materials described above are formed by using, for example, a deposition method (a resistive heating method). In this case, the substrate stage is set at predetermined temperature. This makes it possible to control the areal density of domains in the organic photoelectric conversion layer 12. Finally, the on-chip lens layer 52 is disposed that includes the plurality of on-chip lenses 52L on the front surface thereof. As described above, the photoelectric conversion element 1 illustrated in FIG. 1 is completed.

It is to be noted that, in a case where another organic layer (e.g., an electron blocking layer or the like) is formed on or under the organic photoelectric conversion layer 12 as described above, it is desirable to continuously form the other organic layer (by a vacuum-consistent process) in a vacuum step. In addition, the method of forming the organic photoelectric conversion layer 12 is not necessarily limited to the method using a vacuum deposition method, but another method, for example, a spin-coating technique, a printing technique, or the like may be used.

In a case where light enters the organic photoelectric conversion section 10 through the on-chip lens 52L in the photoelectric conversion element 1, the light passes through the organic photoelectric conversion section 10 and the inorganic photoelectric conversion sections 32B and the 32R in this order and the respective pieces of light of green, blue, and red are photoelectrically converted in the passing process. The following describes an operation of acquiring signals of the respective colors.

### Acquisition of Green Color Signal by Organic Photoelectric Conversion Section 10

First, the green light of the pieces of light inputted into the photoelectric conversion element 1 is selectively detected (absorbed) and photoelectrically converted by the organic photoelectric conversion section 10.

The organic photoelectric conversion section 10 is coupled to the gate Gamp of the amplifier transistor AMP and the floating diffusion FD3 through the through electrode 34. The electron of the electron-hole pair generated in the organic photoelectric conversion section 10 is thus taken out from the lower electrode 11 side, transferred to the second surface 30S2 side of the semiconductor substrate 30 through the through electrode 34, and accumulated in the floating diffusion FD3. At the same time as this, the amplifier transistor AMP modulates the amount of electric charge generated in the organic photoelectric conversion section 10 into a voltage.

In addition, the reset gate Grst of the reset transistor RST is disposed next to the floating diffusion FD3. This causes the reset transistor RST to reset the electric charge accumulated in the floating diffusion FD3.

Here, the organic photoelectric conversion section 10 is coupled to not only the amplifier transistor AMP, but also the floating diffusion FD3 through the through electrode 34, making it possible for the reset transistor RST to easily reset the electric charge accumulated in the floating diffusion FD3.

In contrast, in a case where the through electrode 34 and the floating diffusion FD3 are not coupled, it is difficult to reset the electric charge accumulated in the floating diffusion FD3, resulting in application of a large voltage to pull out the electric charge to the upper electrode 13 side. Accordingly, there is a possibility that the organic photoelectric conversion layer 12 is damaged. In addition, a structure that allows for resetting in a short period of time leads to increased dark-time noise and results in a trade-off. This structure is thus difficult.

### Acquisition of Blue Color Signal and Red Color Signal by Inorganic Photoelectric Conversion Sections 32B and 32R

Subsequently, the blue light and the red light of the pieces of light passing through the organic photoelectric conversion section 10 are respectively absorbed in order and photoelectrically converted in the inorganic photoelectric conversion section 32B and the inorganic photoelectric conversion section 32R. In the inorganic photoelectric conversion section 32B, electrons corresponding to the inputted blue light are accumulated in the n-region of the inorganic photoelectric conversion section 32B and the accumulated electrons are transferred to the floating diffusion FD1 by the vertical transistor Tr1. Similarly, in the inorganic photoelectric conversion section 32R, electrons corresponding to the inputted red light are accumulated in the n-region of the inorganic photoelectric conversion section 32R and the accumulated electrons are transferred to the floating diffusion FD2 by the transfer transistor Tr2.

### 1-3. Workings and Effects

As described above, an organic photoelectric conversion element used for an organic thin-film solar cell, an organic imaging element, or the like adopts a bulk heterostructure in which a p-type organic semiconductor and an n-type organic semiconductor are mixed. However, organic semiconductors have low conductive characteristics and the organic photoelectric conversion element is thus unable to obtain sufficient quantum efficiency. Therefore, there is a problem that an electric output signal is easily delayed with respect to the incident light.

In general, it has been found that molecular orientation is important for the conduction of organic semiconductors. The same applies to an organic photoelectric conversion element having a bulk heterostructure. It has been known that, in an organic photoelectric conversion element in which a conduction direction is perpendicular to a substrate, it is generally preferable that the organic semiconductor be oriented parallel with the substrate. Therefore, as described above, various measures are taken to increase the horizontal orientation of an organic semiconductor included in an organic photoelectric conversion layer.

In addition, the size and dispersion state of domains of the organic semiconductor in the layer are important for the conduction of the organic semiconductor in addition to molecular light distribution.

In contrast, in the photoelectric conversion element 1 according to the present embodiment, the organic photoelectric conversion layer 12 includes domains in a horizontal cross section. The domains are formed by using one or more organic semiconductor materials (e.g., p-type semiconductors). This increases the probability that electric charge (electrons and holes) moves to the lower electrode 11 and the upper electrode 13 through the domains. The electric charge (electrons and holes) results from exciton separation in the domains in the organic photoelectric conversion layer 12 irradiated with light.

As described above, in the photoelectric conversion element 1 according to the present embodiment, the organic photoelectric conversion layer 12 is formed that includes one or more domains in a horizontal cross section. This facilitates electric charge (electrons and holes) generated in the organic photoelectric conversion layer 12 to move to the lower electrode 11 and the upper electrode 13. The one or more domains are each formed by using an organic semiconductor material. This allows both high external quantum efficiency and favorable afterimage characteristics to be achieved.

In addition, in the present embodiment, the areal density of domains in the organic photoelectric conversion layer 12 is increased and the organic photoelectric conversion layer 12 has substantially the same areal density of domains at any positions in the film thickness direction. Specifically, the areal density (the number of domains/unit area parallel with the substrate surface of the semiconductor substrate 30) of domains in the organic photoelectric conversion layer 12 is 1500 domains/square micron or more. More preferably, the areal density (the number of domains/unit area parallel with the substrate surface of the semiconductor substrate 30) of domains in the organic photoelectric conversion layer 12 is 2500 domains/square micron or more. This further increases the probability that electric charge moves to the lower electrode 11 and the upper electrode 13 and makes it possible to further increase high external quantum efficiency and favorable afterimage characteristics.

Further, in the present embodiment, each of a plurality of domains in the organic photoelectric conversion layer 12 has a percolation structure in which the domain vertically extends through the organic photoelectric conversion layer 12 in the film thickness direction (the Y axis direction) and at least a portion of the domains is in contact with one or both of the lower electrode 11 and the upper electrode 13. This makes it possible to further increase the probability that electric charge generated in the organic photoelectric conversion layer 12 moves to the lower electrode 11 or the upper electrode 13 through the domains.

Still further, in the present embodiment, each of a plurality of domains in the organic photoelectric conversion layer 12 includes a crystal of an organic semiconductor material. The organic photoelectric conversion layer 12 is formed to cause the planar projected area ratio obtained by projecting the organic photoelectric conversion layer 12 in the film thickness direction to be 0.5 or less. This makes it possible to further increase the movement efficiency of electric charge while maintaining the generation of excitons necessary for photoelectric conversion.

Next, a modification example of the present disclosure is described. It is to be noted that components corresponding to those of the photoelectric conversion element 1 according to the embodiment described above are denoted by the same reference numerals and description thereof is omitted.

### 2. MODIFICATION EXAMPLES

### 2-1. Modification Example 1

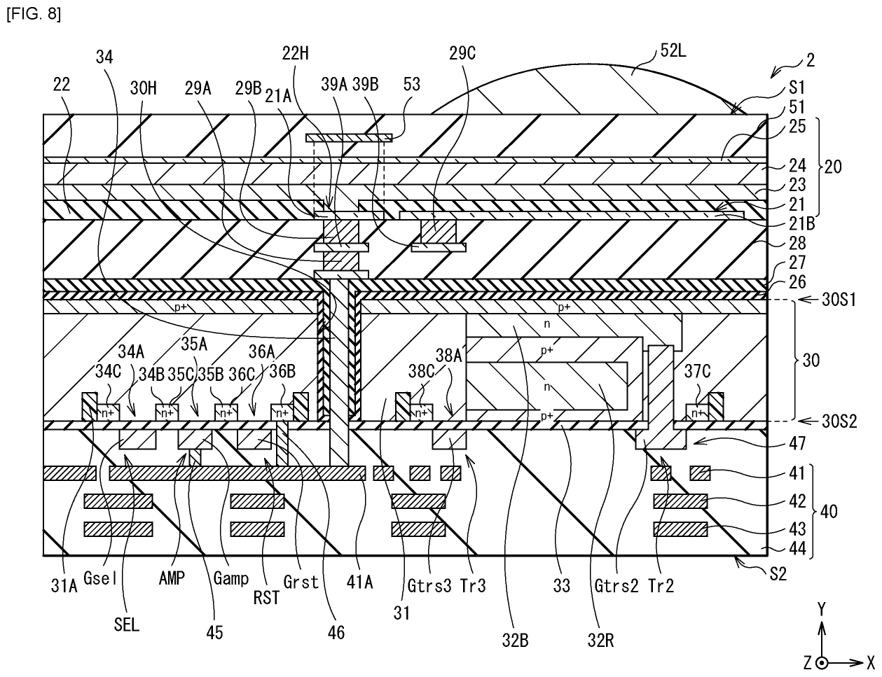

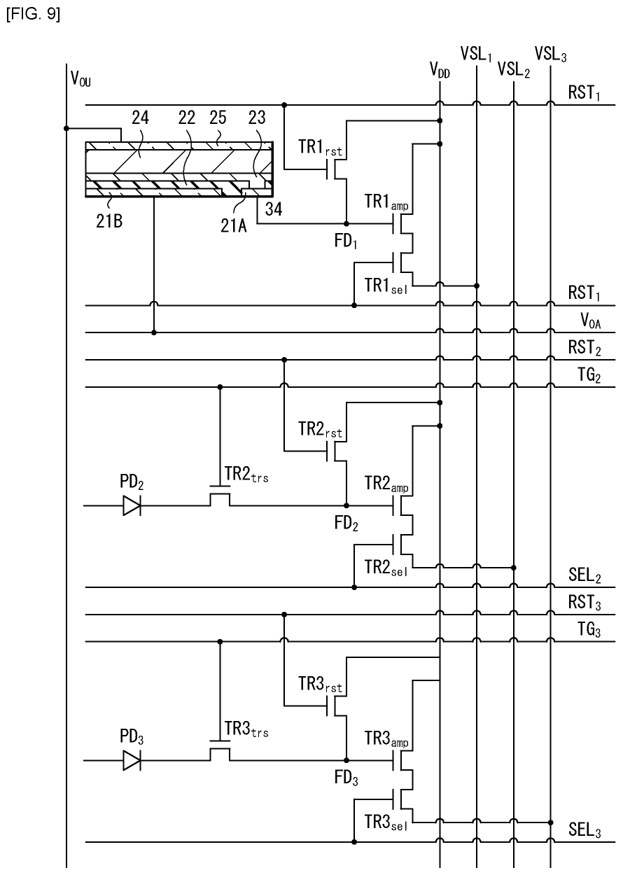

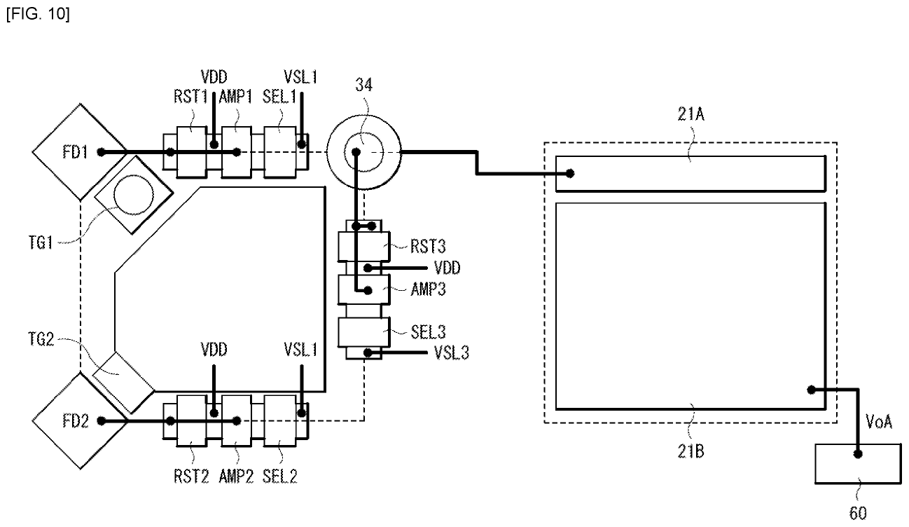

FIG. 8 illustrates an example of a cross-sectional configuration of an imaging element (a photoelectric conversion element 2) according to a modification example 1 of the present disclosure. FIG. 9 is an equivalent circuit diagram of the photoelectric conversion element 2 illustrated in FIG. 8. FIG. 10 schematically illustrates the disposition of a lower electrode 21 of the photoelectric conversion element 2 illustrated in FIG. 8 and a transistor included in a controller. The photoelectric conversion element 2 is included, for example, in one pixel (the unit pixel P) in the solid-state imaging device (the imaging device 100) such as a back-illuminated (back light receiving) CCD image sensor or CMOS image sensor as in the embodiment described above. Although described in detail below, the lower electrode 21 of the photoelectric conversion element 2 according to the present modification example includes a readout electrode 21A and an accumulation electrode 21B. The photoelectric conversion element 2 according to the present modification example is different from the photoelectric conversion element 1 according to the embodiment described above on this point. The lower electrode 21 is included in an organic photoelectric conversion section 20. The readout electrode 21A and the accumulation electrode 21B are separated from each other with an insulating layer 22 interposed in between.

In the organic photoelectric conversion section 20, the lower electrode 21, a semiconductor layer 23, an organic photoelectric conversion layer 24, and an upper electrode 25 are stacked in this order from the first surface (the surface 30S1) side of the semiconductor substrate 30. In addition, the insulating layer 22 is provided between the lower electrode 21 and the semiconductor layer 23. The lower electrode 21 is separately formed, for example, for each of the photoelectric conversion elements 2 and includes the readout electrode 21A and the accumulation electrode 21B that are separated from each other with the insulating layer 22 interposed in between as described above. The readout electrode 21A of the lower electrode 21 is electrically coupled to the semiconductor layer 23 through an opening 22H provided in the insulating layer 22. FIG. 8 illustrates an example in which the semiconductor layer 23, the organic photoelectric conversion layer 24, and the upper electrode 25 are provided as continuous layers common to the plurality of photoelectric conversion elements 2, but the semiconductor layer 23, the organic photoelectric conversion layer 24, and the upper electrode 25 may be separately formed for each of the photoelectric conversion elements 2. For example, there are provided a dielectric layer 26, an insulating layer 27, and an inter-layer insulating layer 28 between the first surface (the surface 30S1) of the semiconductor substrate 30 and the lower electrode 21. There is provided a protective layer 51 on the upper electrode 25. There is provided a light shielding film 53, for example, at the position corresponding to the readout electrode 21A in the protective layer 51. It is sufficient if this light shielding film 53 is provided to cover the region of the readout electrode 21A in direct contact with at least the semiconductor layer 23 without overlapping with at least the accumulation electrode 21B. There are provided, above the protective layer 51, a planarization layer (not illustrated) and an optical member such as the on-chip lens 52L.

The through electrode 34 is provided between the first surface (the surface 30S1) and the second surface (the surface 30S2) of the semiconductor substrate 30 as in the embodiment described above. This through electrode 34 is electrically coupled to the readout electrode 21 of the organic photoelectric conversion section 20 and the organic photoelectric conversion section 20 is coupled to a gate Gamp of the amplifier transistor AMP and one source/drain region 36B of the reset transistor RST (a reset transistor Tr1rst) through the through electrode 34. The reset transistor RST (the reset transistor Tr1rst) also serves as the floating diffusion FD1. This allows the photoelectric conversion element 2 to transfer electric charge generated in the organic photoelectric conversion section 20 on the first surface (the surface 30S21) side of the semiconductor substrate 30 to the second surface (the surface 30S2) side of the semiconductor substrate 30 in a favorable manner, thus making it possible to increase the characteristics.

The lower end of the through electrode 34 is coupled to the coupling section 41A in the wiring layer 41 and the coupling section 41A and the gate Gamp of the amplifier transistor AMP are coupled through the lower first contact 45. The coupling section 41A and the floating diffusion FD1 (the region 36B) are coupled, for example, through the lower second contact 46. The upper end of the through electrode 34 is coupled to the readout electrode 21A, for example, through an upper first contact 29A, a pad section 39A, and an upper second contact 29B.

The through electrode 34 is provided, for example, for each organic photoelectric conversion section 20 in the photoelectric conversion element 2. The through electrode 34 has a function of a connector for the organic photoelectric conversion section 20 and the gate Gamp of the amplifier transistor AMP and the floating diffusion FD1 and serves as a transmission path for electric charge generated in the organic photoelectric conversion section 20.

The reset gate Grst of the reset transistor RST is disposed next to the floating diffusion FD1 (the one source/drain region 36B of the reset transistor RST). This makes it possible to cause the reset transistor RST to reset the electric charge accumulated in the floating diffusion FD1.

The organic photoelectric conversion section 20 is an organic photoelectric conversion element that absorbs the light corresponding to a portion or all of selective wavelength regions (e.g., 400 nm or more and 700 nm or less) to generate an electron-hole pair.

As described above, the lower electrode 21 includes the readout electrode 21A and the accumulation electrode 21B that are separately formed. The readout electrode 21A is for transferring electric charge generated in the organic photoelectric conversion layer 24 to the floating diffusion FD1. The readout electrode 21A is coupled to the floating diffusion FD1, for example, through the upper second contact 29B, the pad section 39A, the upper first contact 29A, the through electrode 34, the coupling section 41A, and the lower second contact 46. The accumulation electrode 21B is for accumulating electrons of the electric charge generated in the organic photoelectric conversion layer 24 in the semiconductor layer 23 as signal charge. The accumulation electrode 21B is provided in a region that directly faces the light receiving surfaces of inorganic photoelectric conversion sections 32G and 32R formed in the semiconductor substrate 30 and covers these light receiving surfaces. It is preferable that the accumulation electrode 21B be larger than the readout electrode 21A. This makes it possible to accumulate a large amount of electric charge. As illustrated in FIG. 10, a voltage application circuit 60 is coupled to the accumulation electrode 21B through a wiring line.

The lower electrode 21 includes an electrically conductive film having light transmissivity as with that of the lower electrode 11 according to the embodiment described above.

The semiconductor layer 23 is provided in a lower layer of the organic photoelectric conversion layer 24. Specifically, the semiconductor layer 23 is provided between the insulating layer 22 and the organic photoelectric conversion layer 24. The semiconductor layer 23 is for accumulating signal charge generated in the organic photoelectric conversion layer 24. It is preferable that the semiconductor layer 23 be formed by using a material having higher electric charge mobility and having a larger band gap than those of the organic photoelectric conversion layer 24. For example, it is preferable that the band gap of a material included in the semiconductor layer 23 be 3.0 eV or more. Examples of such a material include an oxide semiconductor material such as IGZO, an organic semiconductor material, and the like. Examples of the organic semiconductor material include transition metal dichalcogenide, silicon carbide, diamond, graphene, a carbon nanotube, a fused polycyclic hydrocarbon compound, a fused heterocyclic compound, and the like. The thickness of the semiconductor layer 23 is, for example, 10 nm or more and 300 nm or less. The semiconductor layer 23 including the materials described above is provided in a lower layer of the organic photoelectric conversion layer 24. This makes it possible to prevent electric charge recombination while the electric charge is accumulated and increase the transfer efficiency.

The organic photoelectric conversion layer 24 converts optical energy to electric energy. The organic photoelectric conversion layer 24 includes components similar to those of the organic photoelectric conversion layer 12 according to the embodiment described above.

The upper electrode 25 includes an electrically conductive film having light transmissivity as with that of the upper electrode 13 according to the embodiment described above.

It is to be noted that there may be provided other layers between the semiconductor layer 23 and the organic photoelectric conversion layer 24 and between the organic photoelectric conversion layer 24 and the upper electrode 25. For example, as with the photoelectric conversion element 1 illustrated in FIG. 5, the buffer layers 17A and 17B may be provided, for example, between the organic photoelectric conversion layer 24 and the lower electrode 21 or between the organic photoelectric conversion layer 24 and the upper electrode 25 or the buffer layers 17A and 17B may be provided both between the organic photoelectric conversion layer 24 and the lower electrode 21 and between the organic photoelectric conversion layer 24 and the upper electrode 25.

The insulating layer 22 is for electrically separating the accumulation electrode 21B and the semiconductor layer 23. The insulating layer 22 is provided, for example, on the inter-layer insulating layer 28 to cover the lower electrode 21. In addition, the insulating layer 22 is provided with the opening 22H above the readout electrode 21A of the lower electrode 21. The readout electrode 21A and the semiconductor layer 23 are electrically coupled through this opening 22H. The insulating layer 22 includes, for example, a single-layer film including one of silicon oxide, silicon nitride, silicon oxynitride, and the like, or a stacked film including two or more thereof. The thickness of the insulating layer 22 is, for example, 20 nm to 500 nm.

The dielectric layer 26 is for preventing the reflection of light caused by a refractive index difference between the semiconductor substrate 30 and the insulating layer 27. It is preferable that a material of the dielectric layer 26 be a material having a refractive index between the refractive index of the semiconductor substrate 30 and the refractive index of the insulating layer 27. Further, it is preferable that a material allowing a film to be formed having, for example, negative fixed electric charge be used as a material of the dielectric layer 26. Alternatively, it is preferable that a semiconductor material or an electrically conductive material having a wider band gap than that of the semiconductor substrate 30 be used as a material of the dielectric layer 26. This makes it possible to suppress the generation of dark currents at the interface of the semiconductor substrate 30. Such a material includes hafnium oxide, aluminum oxide, zirconium oxide, tantalum oxide, titanium oxide, lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, hafnium nitride, aluminum nitride, hafnium oxynitride, aluminum oxynitride, and the like.

The insulating layer 27 is provided on the dielectric layer 26 that is formed on the first surface (the surface 30S1) of the semiconductor substrate 30 and the side surface of the through hole 30H. The insulating layer 27 is for electrically insulating the through electrode 34 and the semiconductor substrate 30 from each other. Examples of a material of the insulating layer 27 include silicon oxide, TEOS, silicon nitride, silicon oxynitride, and the like.

The inter-layer insulating layer 28 includes, for example, a single-layer film including one of silicon oxide, TEOS, silicon nitride, silicon oxynitride, and the like or a stacked film including two or more thereof.

The semiconductor substrate 30 includes, for example, an n-type silicon substrate and includes the p-well 31 in a predetermined region (e.g., a pixel section 1a). The second surface (the surface 30S2) of the p-well 31 is provided with the transfer transistors Tr2 and Tr3 described above, the amplifier transistor AMP, the reset transistor RST, a selection transistor SEL, and the like.

The reset transistor RST (the reset transistor Tr1rst) resets the electric charge transferred from the organic photoelectric conversion section 20 to the floating diffusion FD1 and includes, for example, a MOS transistor. Specifically, the reset transistor Tr1rst includes the reset gate Grst, a channel formation region 36A, and the source/drain regions 36B and 36C. The reset gate Grst is coupled to a reset line RST1. The one source/drain region 36B of the reset transistor Tr1rst also serves as the floating diffusion FD1. The other source/drain region 36C included in the reset transistor Tr1rst is coupled to a power supply VDD.

The amplifier transistor AMP is a modulation element that modulates, into a voltage, the amount of electric charge generated in the organic photoelectric conversion section 20 and includes, for example, a MOS transistor. Specifically, the amplifier transistor AMP includes the gate Gamp, a channel formation region 35A, and the source/drain regions 35B and 35C. The gate Gamp is coupled to the readout electrode 21A and the one source/drain region 36B (the floating diffusion FD1) of the reset transistor Tr1rst through the lower first contact 45, the coupling section 41A, the lower second contact 46, the through electrode 34, and the like. In addition, the one source/drain region 35B shares a region with the other source/drain region 36C included in the reset transistor Tr1rst and is coupled to the power supply VDD.

The selection transistor SEL (a selection transistor TR1sel) includes a gate Gsel, a channel formation region 34A, and source/drain regions 34B and 34C. The gate Gsel is coupled to a selection line SEL1. In addition, the one source/drain region 34B shares a region with the other source/drain region 35C included in the amplifier transistor AMP and the other source/drain region 34C is coupled to a signal line (a data output line) VSL1.

The transfer transistor Tr2 (a transfer transistor TR2trs) is for transferring signal charge to the floating diffusion FD2. The signal charge is generated and accumulated in the inorganic photoelectric conversion section 32G and corresponds to blue. The inorganic photoelectric conversion section 32G is formed at a deep position from the second surface (the surface 30S2) of the semiconductor substrate 30 and it is thus preferable that the transfer transistor TR2trs of the inorganic photoelectric conversion section 32G include a vertical transistor. In addition, the transfer transistor TR2trs is coupled to a transfer gate line TG2. Further, the floating diffusion FD2 is provided in a region 37C near a gate Gtrs2 of the transfer transistor TR2trs. Electric charge accumulated in the inorganic photoelectric conversion section 32G is read out by the floating diffusion FD2 through a transfer channel formed along the gate Gtrs2.

The transfer transistor Tr3 (the transfer transistor TR3trs) transfers, to the floating diffusion FD3, the signal charge generated and accumulated in the inorganic photoelectric conversion section 32R. The signal charge corresponds to red. The transfer transistor Tr3 (the transfer transistor TR3trs) includes, for example, a MOS transistor. In addition, the transfer transistor TR3trs is coupled to a transfer gate line TG3. Further, the floating diffusion FD3 is provided in a region 38C near a gate Gtrs3 of the transfer transistor TR3trs. Electric charge accumulated in the inorganic photoelectric conversion section 32R is read out by the floating diffusion FD3 through a transfer channel formed along the gate Gtrs3.

The second surface (the surface 30S2) side of the semiconductor substrate 30 is further provided with a reset transistor TR2rst, an amplifier transistor TR2amp, and a selection transistor TR2sel that are included in a controller of the inorganic photoelectric conversion section 32G. In addition, there are provided a reset transistor TR3rst, an amplifier transistor TR3amp, and a selection transistor TR3sel that are included in a controller of the inorganic photoelectric conversion section 32R.

The reset transistor TR2rst includes a gate, a channel formation region, and a source/drain region. The gate of the reset transistor TR2rst is coupled to a reset line RST2 and the one source/drain region of the reset transistor TR2rst is coupled to the power supply VDD. The other source/drain region of the reset transistor TR2rst also serves as the floating diffusion FD2.

The amplifier transistor TR2amp includes a gate, a channel formation region, and a source/drain region. The gate is coupled to the other source/drain region (the floating diffusion FD2) of the reset transistor TR2rst. In addition, the one source/drain region included in the amplifier transistor TR2amp shares a region with the one source/drain region included in the reset transistor Tr2rst and is coupled to the power supply VDD.

The selection transistor TR2sel includes a gate, a channel formation region, and a source/drain region. The gate is coupled to a selection line SEL2. In addition, the one source/drain region included in the selection transistor TR2sel shares a region with the other source/drain region included in the amplifier transistor TR2amp. The other source/drain region included in the selection transistor TR2sel is coupled to a signal line (a data output line) VSL2.

The reset transistor TR3rst includes a gate, a channel formation region, and a source/drain region. The gate of the reset transistor TR3rst is coupled to a reset line RST3 and the one source/drain region included in the reset transistor TR3rst is coupled to the power supply VDD. The other source/drain region included in the reset transistor TR3rst also serves as the floating diffusion FD3.

The amplifier transistor TR3amp includes a gate, a channel formation region, and a source/drain region. The gate is coupled to the other source/drain region (the floating diffusion FD3) included in the reset transistor TR3rst. In addition, the one source/drain region included in the amplifier transistor TR3amp shares a region with the one source/drain region included in the reset transistor Tr3rst and is coupled to the power supply VDD.

The selection transistor TR3sel includes a gate, a channel formation region, and a source/drain region. The gate is coupled to a selection line SEL3. In addition, the one source/drain region included in the selection transistor TR3sel shares a region with the other source/drain region included in the amplifier transistor TR3amp. The other source/drain region included in the selection transistor TR3sel is coupled to a signal line (a data output line) VSL3.

The reset lines RST1, RST2, and RST3, the selection lines SEL1, SEL2, and SEL3, and the transfer gate lines TG2 and TG3 are each coupled to a vertical drive circuit 112 included in a drive circuit. The signal lines (the data output lines) VSL1, VSL2, and VSL3 are coupled to a column signal processing circuit 113 included in the drive circuit.

As described above, the present technology is also applicable to a photoelectric conversion element (the photoelectric conversion element 2) in which the lower electrode 21 includes the readout electrode 21A and the accumulation electrode 21B that are separated from each other with the insulating layer 22 interposed in between. In other words, in the photoelectric conversion element 2 according to the present modification example, the organic photoelectric conversion layer 24 is formed to include domains in a horizontal cross section. This facilitates electric charge (electrons and holes) generated in the organic photoelectric conversion layer 24 to move to the lower electrode 21 and the upper electrode 25 and makes it possible to obtain an effect similar to that of the embodiment described above. Each of the domains is formed by using one or more organic semiconductor materials.

### 2-2. Modification Example 2

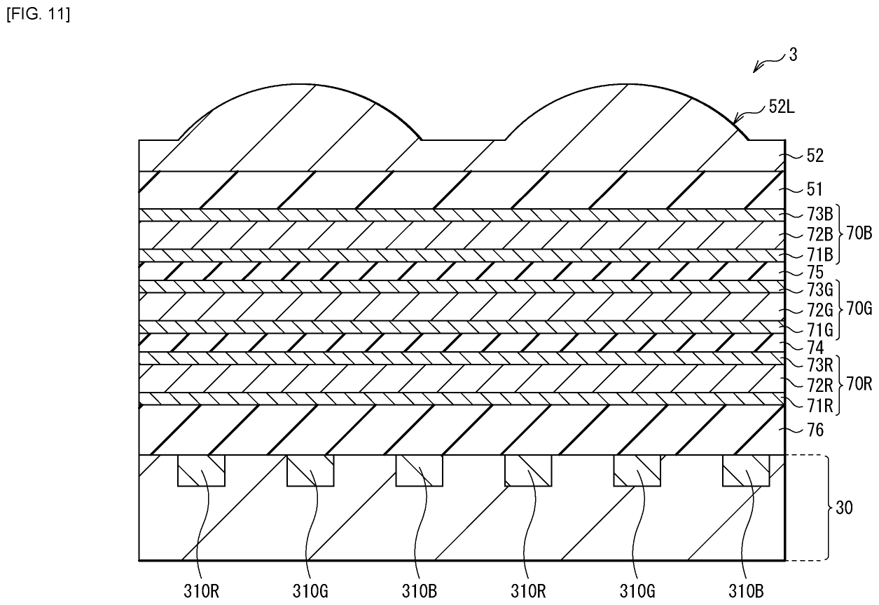

FIG. 11 illustrates a cross-sectional configuration of a photoelectric conversion element (a photoelectric conversion element 3) according to a modification example 2 of the present disclosure. The photoelectric conversion element 3 is included, for example, in the one unit pixel Pin the solid-state imaging element (the imaging device 100) such as a back-illuminated CCD image sensor or CMOS image sensor as with the photoelectric conversion element 1 according to the embodiment or the like described above. The photoelectric conversion element 3 according to the present modification example has a configuration in which a red photoelectric conversion section 70R, a green photoelectric conversion section 70G, and a blue photoelectric conversion section 70B are stacked in this order on the semiconductor substrate 30 with the insulating layer 76 interposed in between.

The red photoelectric conversion section 70R, the green photoelectric conversion section 70G, and the blue photoelectric conversion section 70B respectively include organic photoelectric conversion layers 72R, 72G, and 72B between the respective pairs of electrodes. Specifically, the red photoelectric conversion section 70R, the green photoelectric conversion section 70G, and the blue photoelectric conversion section 70B respectively include the organic photoelectric conversion layers 72R, 72G, and 72B between a first electrode 71R and a second electrode 73R, between a first electrode 71G and a second electrode 73G, and between a first electrode 71B and a second electrode 73B.

The on-chip lens 52L is provided on the blue photoelectric conversion section 70B with the protective layer 51 and the on-chip lens layer 51 interposed in between. There are provided a red electricity storage layer 310R, a green electricity storage layer 310G, and a blue electricity storage layer 310B in the semiconductor substrate 30. The pieces of light inputted to the on-chip lens 52L are photoelectrically converted by the red photoelectric conversion section 70R, the green photoelectric conversion section 70G, and the blue photoelectric conversion section 70B. The signal charge is transmitted from the red photoelectric conversion section 70R to the red electricity storage layer 310R, from the green photoelectric conversion section 70G to the green electricity storage layer 310G, and from the blue photoelectric conversion section 70B to the blue electricity storage layer 310B. Although the signal charge may be either electrons or holes generated by photoelectric conversion, the following gives description by exemplifying a case where electrons are read as signal charge.

The semiconductor substrate 30 includes, for example, a p-type silicon substrate. The red electricity storage layer 310R, the green electricity storage layer 310G, and the blue electricity storage layer 310B provided in this semiconductor substrate 30 each include an n-type semiconductor region. The signal charge (electrons) supplied from the red photoelectric conversion section 70R, the green photoelectric conversion section 70G, and the blue photoelectric conversion section 70B is accumulated in the n-type semiconductor regions. The n-type semiconductor regions of the red electricity storage layer 310R, the green electricity storage layer 310G, and the blue electricity storage layer 310B are formed, for example, by doping the semiconductor substrate 30 with n-type impurities such as phosphorus (P) or arsenic (As). It is to be noted that the semiconductor substrate 30 may be provided on a support substrate (not illustrated) including glass or the like.

The semiconductor substrate 30 includes a pixel transistor for reading out the respective electrons from the red electricity storage layer 310R, the green electricity storage layer 310G, and the blue electricity storage layer 310B and transferring the read electrons to, for example, a vertical signal line (a vertical signal line Lsig in FIG. 12 described below). A floating diffusion of this pixel transistor is provided in the semiconductor substrate 30 and this floating diffusion is coupled to the red electricity storage layer 310R, the green electricity storage layer 310G, and the blue electricity storage layer 310B. The floating diffusion includes an n-type semiconductor region.

The insulating layer 76 includes, for example, silicon oxide, silicon nitride, silicon oxynitride, hafnium oxide, or the like. The insulating layer 76 may include a plurality of types of insulating films that is stacked. The insulating layer 76 may include an organic insulating material. This insulating layer 76 is provided with respective plugs and respective electrodes for coupling the red electricity storage layer 310R and the red photoelectric conversion section 70R, the green electricity storage layer 310G and the green photoelectric conversion section 70G, and the blue electricity storage layer 310B and the blue photoelectric conversion section 70B.

The red photoelectric conversion section 70R includes the first electrode 71R, an organic photoelectric conversion layer 72R, and the second electrode 73R in this order from positions close to the semiconductor substrate 30. The green photoelectric conversion section 70G includes the first electrode 71G, an organic photoelectric conversion layer 72G, and the second electrode 73G in this order from positions close to the red photoelectric conversion section 70R. The blue photoelectric conversion section 70B includes the first electrode 71B, an organic photoelectric conversion layer 72B, and the second electrode 73B in this order from positions close to the green photoelectric conversion section 70G. There is provided an insulating layer 44 between the red photoelectric conversion section 70R and the green photoelectric conversion section 70G and there is provided an insulating layer 75 between the green photoelectric conversion section 70G and the blue photoelectric conversion section 70B. Light of red (e.g., a wavelength of 600 nm or more and less than 700 nm) is selectively absorbed in the red photoelectric conversion section 70R; light of green (e.g., a wavelength of 480 nm or more and less than 600 nm) is selectively absorbed in the green photoelectric conversion section 70G; and light of blue (e.g., a wavelength of 400 nm or more and less than 480 nm) is selectively absorbed in the blue photoelectric conversion section 70B, generating electron-hole pairs.

The first electrode 71R extracts signal charge generated in the organic photoelectric conversion layer 72R; the first electrode 71G extracts signal charge generated in the organic photoelectric conversion layer 72G; and the first electrode 71B extracts signal charge generated in the organic photoelectric conversion layer 72B. The first electrodes 71R, 71G, and 71B are each provided for each pixel, for example. These first electrodes 71R, 71G, and 71B each include, for example, a light transmissive electrically conductive material, specifically, ITO. The first electrodes 71R, 71G, and 71B may each include, for example, a tin oxide-based material or a zinc oxide-based material. The tin oxide-based material is obtained by doping tin oxide with a dopant. Examples of the zinc oxide-based material include aluminum zinc oxide in which aluminum is added to zinc oxide as a dopant, gallium zinc oxide in which gallium is added to zinc oxide as a dopant, indium zinc oxide in which indium is added to zinc oxide as a dopant, and the like. In addition, it is also possible to use IGZO, CuI, InSbO₄, ZnMgO, CuInO₂, MgIn₂O₄, CdO, ZnSnO₃, and the like. The thickness of each of the first electrodes 71R, 71G, and 71B is, for example, 50 nm to 500 nm.

For example, respective electron transport layers may be provided between the first electrode 71R and the organic photoelectric conversion layer 72R, between the first electrode 71G and the organic photoelectric conversion layer 72G, and between the first electrode 71B and the organic photoelectric conversion layer 72B. The electron transport layers serve to facilitate electrons generated in the organic photoelectric conversion layers 72R, 72G, and 72B to be supplied to the first electrodes 71R, 71G, and 71B and each include, for example, titanium oxide, zinc oxide, or the like. The electron transport layers may each include titanium oxide and zinc oxide that are stacked. The thickness of each of the electron transport layers is, for example, 0.1 nm to 1000 nm. It is preferable that the thickness of each of the electron transport layers be 0.5 nm to 300 nm.

The organic photoelectric conversion layers 72R, 72G, and 72B each absorb light in a selective wavelength region for photoelectric conversion and transmit light in another wavelength region. Here, the light in the selective wavelength region is, for example, light in a wavelength region of a wavelength of 600 nm or more and less than 700 nm in the organic photoelectric conversion layer 72R, light in a wavelength region of a wavelength of 480 nm or more and less than 600 nm, for example, in the organic photoelectric conversion layer 72G, and light in a wavelength region of a wavelength of 400 nm or more and less than 480 nm, for example, in the organic photoelectric conversion layer 72B. The thickness of each of the organic photoelectric conversion layers 72R, 72G, and 72B is, for example, 50 nm or more and less than 500 nm.

Each of the organic photoelectric conversion layers 72R, 72G, and 72B has a configuration similar to that of the organic photoelectric conversion layer 12 according to the embodiment described above.

For example, respective hole transport layers may be provided between the organic photoelectric conversion layer 72R and the second electrode 73R, between the organic photoelectric conversion layer 72G and the second electrode 73G, and between the organic photoelectric conversion layer 72B and the second electrode 73B. The hole transport layers serve to facilitate holes generated in the organic photoelectric conversion layers 72R, 72G, and 72B to be supplied to the second electrodes 73R, 73G, and 73B and each include, for example, molybdenum oxide, nickel oxide, vanadium oxide, or the like. The hole transport layers may each include an organic material such as PEDOT (Poly(3,4-ethylenedioxythiophene) and TPD (N,N′-Bis(3-methylphenyl)-N,N′-diphenylbenzidine). The thickness of each of the hole transport layers is, for example, 0.5 nm or more and 100 nm or less.

The second electrode 73R serves to extract holes generated in the organic photoelectric conversion layer 72R; the second electrode 73G serves to extract holes generated in the organic photoelectric conversion layer 72G; and the second electrode 73B serves to extract holes generated in the organic photoelectric conversion layer 72G. The holes extracted from the second electrodes 73R, 73G, and 73B are, for example, discharged to a p-type semiconductor region (not illustrated) in the semiconductor substrate 30 through respective transmission paths (not illustrated). The second electrodes 73R, 73G, and 73B each include, for example, an electrically conductive material such as gold, silver, copper, and aluminum. As with the first electrodes 71R, 71G, and 71B, the second electrodes 73R, 73G, and 73B may each include a transparent electrically conductive material. In the photoelectric conversion element 3, holes extracted from these second electrodes 73R, 73G, and 73B are discharged. Therefore, for example, in a case where the plurality of photoelectric conversion elements 3 is disposed in the imaging device 100 described below, the second electrodes 73R, 73G, and 73B may be provided in common for each of the photoelectric conversion elements 3 (the unit pixel P). The thickness of each of the second electrodes 73R, 73G, and 73B is, for example, 0.5 nm or more and 100 nm or less.

The insulating layer 74 serves to insulate the second electrode 73R and the first electrode 71G from each other, and the insulating layer 75 serves to insulate the second electrode 73G and the first electrode 71B from each other. The insulating layers 74 and 75 each include, for example, metal oxide, metal sulfide, or an organic material. Examples of the metal oxide include silicon oxide, aluminum oxide, zirconium oxide, titanium oxide, zinc oxide, tungsten oxide, magnesium oxide, niobium oxide, tin oxide, gallium oxide, and the like. Examples of the metal sulfide include zinc sulfide, magnesium sulfide, and the like. It is preferable that the band gap of a material included in each of the insulating layers 74 and 75 be 3.0 eV or more. The thickness of each of the insulating layers 74 and 75 is, for example, 2 nm or more and 100 nm or less.

As described above, the present technology is also applicable to a photoelectric conversion element (the photoelectric conversion element 3) in which the red photoelectric conversion section 70R, the green photoelectric conversion section 70G, and the blue photoelectric conversion section 70B are stacked in this order. The red photoelectric conversion section 70R, the green photoelectric conversion section 70G, and the blue photoelectric conversion section 70B include the respective photoelectric conversion layers (the organic photoelectric conversion layers 72R, 72G, and 72B). Each of the photoelectric conversion layers (the organic photoelectric conversion layers 72R, 72G, and 72B) includes an organic semiconductor material. In other words, in the photoelectric conversion element 3 according to the present modification example, each of the organic photoelectric conversion layers 72R, 72G, and 72B is formed to include domains in a horizontal cross section. This facilitates electric charge (electrons and holes) generated in the organic photoelectric conversion layers 72R, 72G, and 72B to respectively move to the first electrodes 71R, 71G, and 71B and the second electrodes 73R, 73G, and 73B and makes it possible to obtain an effect similar to that of the embodiment described above. Each of the domains is formed by using one or more organic semiconductor materials.

### 3. APPLICATION EXAMPLES

### Application Example 1

FIG. 12 illustrates, for example, an overall configuration of the imaging device 100 in which a photoelectric conversion element (the photoelectric conversion element 1) described in the embodiment or the like described above is used for each of the pixels. This imaging device 100 is a CMOS image sensor. The imaging device 100 includes, on the semiconductor substrate 30, the pixel section 1a as an imaging area and a peripheral circuit unit 130 in a peripheral region of this pixel section 1a. The peripheral circuit unit 130 includes, for example, a row scanning section 131, a horizontal selection section 133, a column scanning section 134, and a system control section 132.

The pixel section 1a includes, for example, the plurality of unit pixels P (corresponding, for example, to the photoelectric conversion elements 1) that is two-dimensionally disposed in a matrix. In these unit pixels P, pixel drive lines Lread (specifically, row selection lines and reset control lines) are disposed for each of pixel rows, for example, and vertical signal lines Lsig are disposed for each of pixel columns. The pixel drive lines Lread are each used to transmit drive signals for reading out signals from pixels. One end of each of the pixel drive lines Lread is coupled to the output end of the row scanning section 131 corresponding to each row.

The row scanning section 131 is a pixel drive section that includes a shift register, an address decoder, and the like and drives each of the unit pixels P of the pixel section 1a on a row basis, for example. A signal outputted from each of the unit pixels P of the pixel rows selected and scanned by the row scanning section 131 is supplied to the horizontal selection section 133 through each of the vertical signal lines Lsig. The horizontal selection section 133 includes an amplifier, a horizontal selection switch, and the like provided for each of the vertical signal lines Lsig.

The column scanning section 134 includes a shift register, an address decoder, and the like and drives each of the horizontal selection switches of the horizontal selection section 133 in order while scanning the horizontal selection switches. The selective scanning by this column scanning section 134 causes signals of the respective pixels transmitted through each of the vertical signal lines Lsig to be outputted to a horizontal signal line 135 in order and causes the signals to be transmitted to the outside of the semiconductor substrate 30 through the horizontal signal line 135.

Circuit portions including the row scanning section 131, the horizontal selection section 133, the column scanning section 134, and the horizontal signal line 135 may be formed directly on the semiconductor substrate 30 or may be disposed on external control IC. In addition, those circuit portions may be formed on another substrate coupled by a cable or the like.

The system control section 132 receives, for example, a clock, data for an instruction about an operation mode, and the like. The clock and the data are supplied from the outside of the semiconductor substrate 30. In addition, the system control section 132 outputs data such as internal information of the imaging device 100. The system control section 132 further includes a timing generator that generates various timing signals and controls the driving of the peripheral circuit such as the row scanning section 131, the horizontal selection section 133, and the column scanning section 134 on the basis of the various timing signals generated by the timing generator.

### Application Example 2

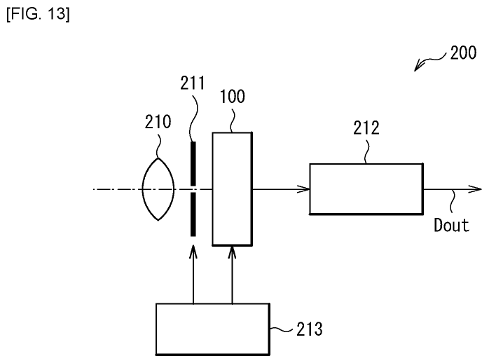

The imaging device 100 described above is applicable, for example, to any type of electronic apparatus (imaging device) having an imaging function. The electronic apparatus (the imaging device) includes a camera system such as a digital still camera and a video camera, a mobile phone having the imaging function, and the like. FIG. 13 illustrates a schematic configuration of a camera 200 as an example thereof. This camera 200 is, for example, a video camera that is able to shoot a still image or a moving image. The camera 200 includes the imaging device 100, an optical system (an optical lens) 210, a shutter device 211, a drive section 213 that drives the imaging device 100 and the shutter device 211, and a signal processing section 212.

The optical system 210 guides image light (incident light) from an object to the pixel section 1a of the imaging device 100. This optical system 210 may include a plurality of optical lenses. The shutter device 211 controls a period of time in which the imaging device 100 is irradiated with light and a period of time in which light is blocked. The drive section 213 controls a transfer operation of the imaging device 100 and a shutter operation of the shutter device 211. The signal processing section 212 performs various types of signal processing on signals outputted from the imaging device 100. An image signal Dout subjected to the signal processing is stored in a storage medium such as a memory or outputted to a monitor or the like.

### 4. PRACTICAL APPLICATION EXAMPLES

### Example of Practical Application to In-Vivo Information Acquisition System

Further, the technology (the present technology) according to the present disclosure is applicable to various products. For example, the technology according to the present disclosure may be applied to an endoscopic surgery system.

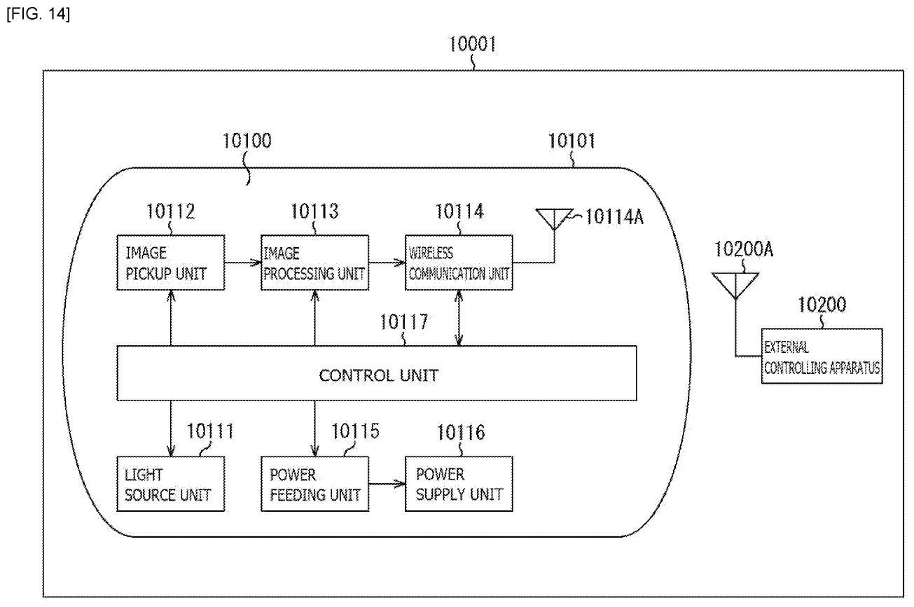

FIG. 14 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 14, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The example of the in-vivo information acquisition system to which the technology according to the present disclosure may be applied has been described above. The technology according to the present disclosure may be applied, for example, to the image pickup unit 10112 among the components described above. This makes it possible to increase the detection accuracy.

### Example of Practical Application to Endoscopic Surgery System

The technology (present technology) according to the present disclosure is applicable to various products. For example, the technology according to the present disclosure may be applied to an endoscopic surgery system.

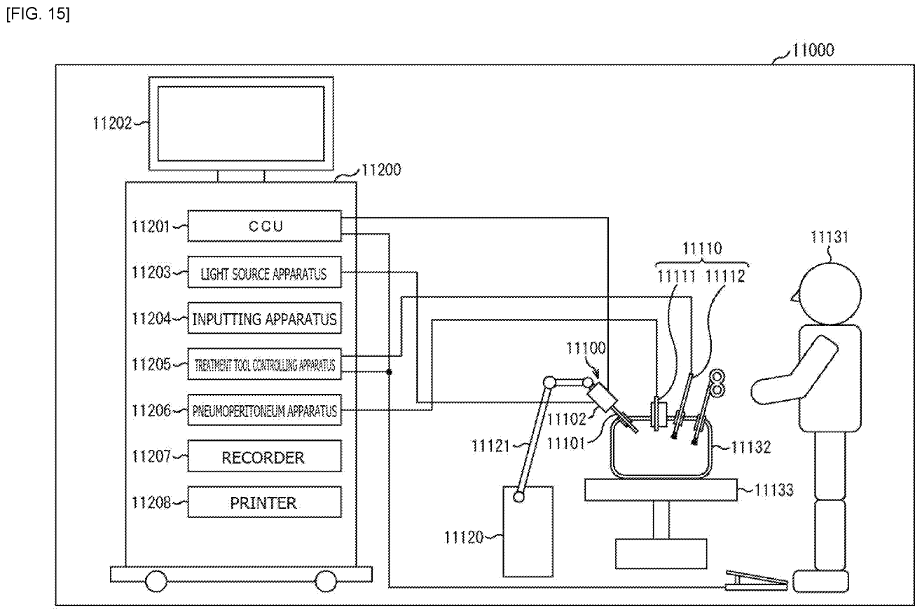

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

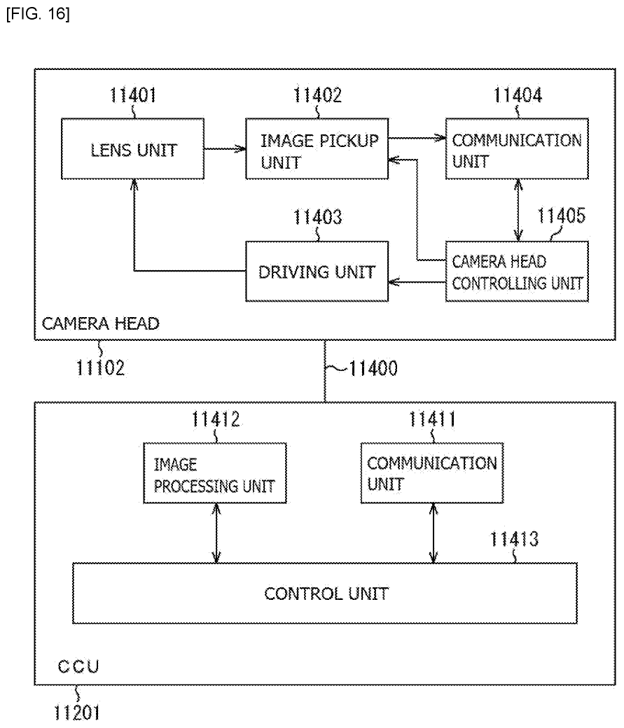

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure may be applied has been described above. The technology according to the present disclosure may be applied to the image pickup unit 11402 among the components described above. Applying the technology according to an embodiment of the present disclosure to the image pickup unit 11402 increases the detection accuracy.

It is to be noted that the endoscopic surgery system has been described here as an example, but the technology according to the present disclosure may be additionally applied to, for example, a microscopic surgery system or the like.

### Example of Practical Application to Mobile Body

The technology according to the present disclosure is applicable to various products. For example, the technology according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, a construction machine, or an agricultural machine (tractor).

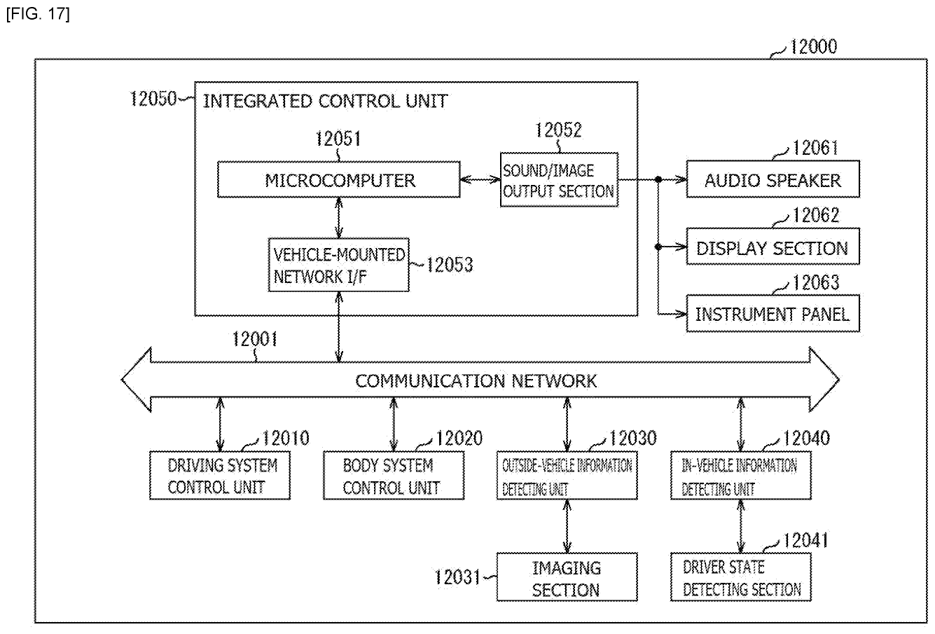

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

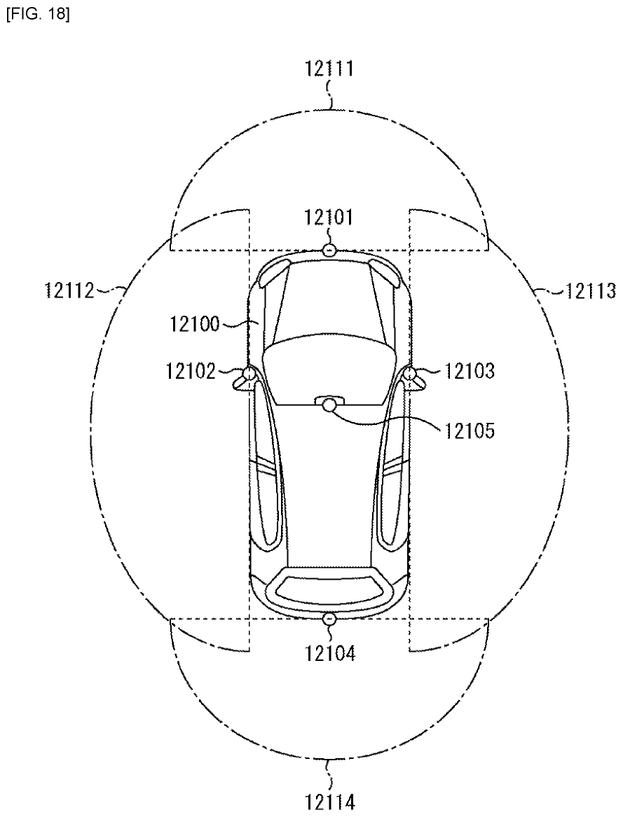

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

### 5. WORKING EXAMPLES

Next, working examples of the present disclosure are described.

### Evaluation of Electric Characteristics

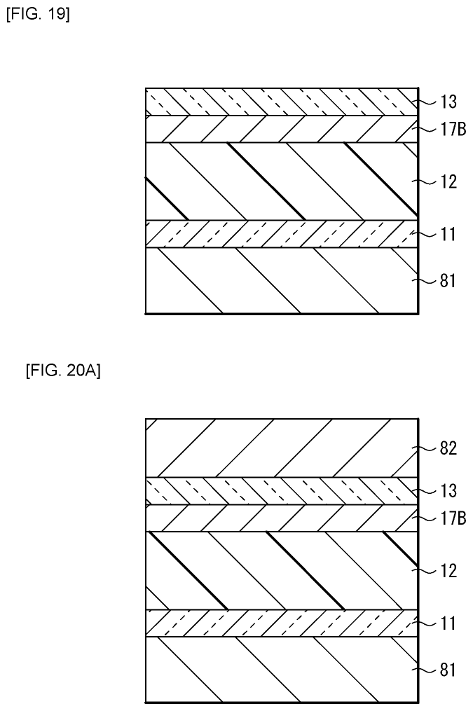

FIG. 19 schematically illustrates a cross-sectional configuration of a photoelectric conversion element fabricated in the present working example. First, after a Si substrate 81 provided with an ITO electrode (the lower electrode 11) having a thickness of 50 nm was cleaned in a UV/ozone process, the organic photoelectric conversion layer 12 was formed at a substrate stage temperature of 27° C. in a resistive heating method while rotating a substrate holder in vacuum of 1×10⁻⁵ Pa or less. For a material of the organic photoelectric conversion layer 12, 3, 6BP-BBTN indicated in Expression (1) below was used as a hole transporting material (a P material), a subphthalocyanine derivative (F6-SubPc-OPh26F2) was used as a light absorber, and fullerene C60 was used as an electron transporting material (an N material). These were concurrently deposited. The ratio of deposition speed was 3, 6BP-BBTN:F6-SubPc-OPh26F2:C60=4:4:2. Film formation was performed to cause the total film thickness to be 230 nm. Subsequently, B4PyPMP was deposited to have a thickness of 5 nm in a vacuum deposition method at a substrate temperature of 0° C. as the buffer layer 17B on the organic photoelectric conversion layer 12. Next, as the upper electrode 13, a film of ITO was formed by sputtering to have a thickness of 100 nm and then subjected to heating treatment at 160° C. As described above, a photoelectric conversion element (Experiment Example 1) including a photoelectric conversion region of 1 mm×1 mm was fabricated.

Additionally, photoelectric conversion elements serving as Experiment Examples 2 and 3 were fabricated. In Experiment Examples 2 and 3, photoelectric conversion elements were fabricated by using a method similar to that of Experiment Example 1 except that the organic photoelectric conversion layers were formed at a substrate temperature of 42° C. (Experiment Example 2) and a substrate temperature of 0° C. (Experiment Example 3).

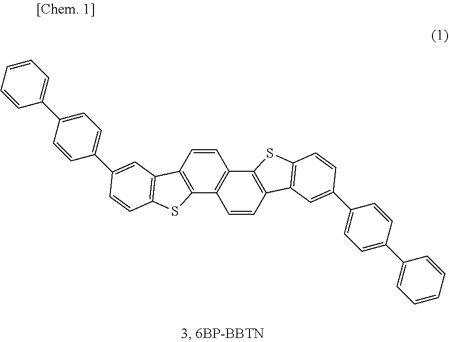 [SMILES: c1ccc(-c2ccc(-c3ccc4sc5c(ccc6c5ccc5c7cc(-c8ccc(-c9ccccc9)cc8)ccc7sc56)c4c3)cc2)cc1]

The responsiveness (the afterimage characteristics) of Experiment Examples 1 to 3 were evaluated. The afterimage characteristics were evaluated by measuring the speed at which the bright current value observed at the time of light irradiation fell after the light irradiation was stopped by using a semiconductor parameter analyzer. Specifically, the amount of light with which the photoelectric conversion element was irradiated from the light source through the filter was set at 1.62 μW/cm2 and the bias voltage to be applied between the electrodes was set at −2.6 V. After a steady current was observed in this state, the light irradiation was stopped and the current was observed decaying. Thereafter, the area surrounded by a current-time curve and the dark current was set as 100% and the time elapsed before the area becomes 3% was considered as an index of the responsiveness. All of these evaluations were made at the room temperature.

In addition, the quantum efficiency (external quantum efficiency; EQE) of Experiment Examples 1 to 3 was evaluated by using a semiconductor parameter analyzer. Specifically, the external photoelectric conversion efficiency was calculated from a bright current value and a dark current value in a case where the amount of light (LED light having a wavelength of 560 nm) with which the photoelectric conversion element was irradiated from the light source through the filter was set at 1.62 μW/cm² and the bias voltage to be applied between the electrodes was set to −2.6 V.

### Transmission Electron Microscope (TEM) Analysis

In addition, TEM observation samples of the organic photoelectric conversion layers corresponding to Experiment Examples 1 to 3 were fabricated and domains of a P material (an organic semiconductor material having a hole transporting property) in each of the layers were observed from the planar direction of the organic photoelectric conversion layers. The domains of the P materials were confirmed by observing transmission images with a transmission electron microscope.

First, a thin sample was fabricated from the region of the organic photoelectric conversion layer of the sample of Experiment Example 1 above by using a focused ion beam (Focused Ion Beam; FIB, HELIOS NANOLAB 400S manufactured by FEI) and a damaged layer of an FIB-processed end surface was then removed by an ion milling machine (Model 1040 manufactured by Fischione). TEM (JEM-300F manufactured by JEOL) observed a transmission image at an accelerating voltage of 300 kV in the state of low irradiation electron beams. The transmission image was observed with the transmission image out of focus, that is, shifted by approximately 1500 nm from the just focus position onto the underside as a defocus condition for observing a domain. Additionally, similar methods were used to perform the transmission microscope analyses of Experiment Examples 2 and 3 above.

TABLE 1

| | | film | | | |
|---|---|---|---|---|---|
| | | formation | | electric characteristics | |
| | | substrate | heating | afterimage | |
| | | temperature | treatment | characteristics | |
| | P material | (° C.) | condition | (ms) | EQE (%) |
| Experiment | 3, 6BP-BBTN | 40 | ANL 160° C. | 1.3 | 80.4 |
| Example 1 | | | | | |
| Experiment | 3, 6BP-BBTN | 26 | ANL 160° C. | 3.5 | 79.8 |
| Example 2 | | | | | |
| Experiment | 3, 6BP-BBTN | 0 | ANL 160° C. | 7.8 | 62.3 |
| Example 3 | | | | | |

FIGS. 21 to 23 schematically illustrate TEM images obtained by enlarging the interference fringe portions of Experiment Examples 1 to 3. The interference fringes (the lattice fringes) of a TEM image each appear as a peak of high points or low points of the signal intensity in accordance with the strength of the contrast thereof. As described above, paired adjacent lines included in an interference fringe correspond to the molecular period of the P material in the long axis direction.

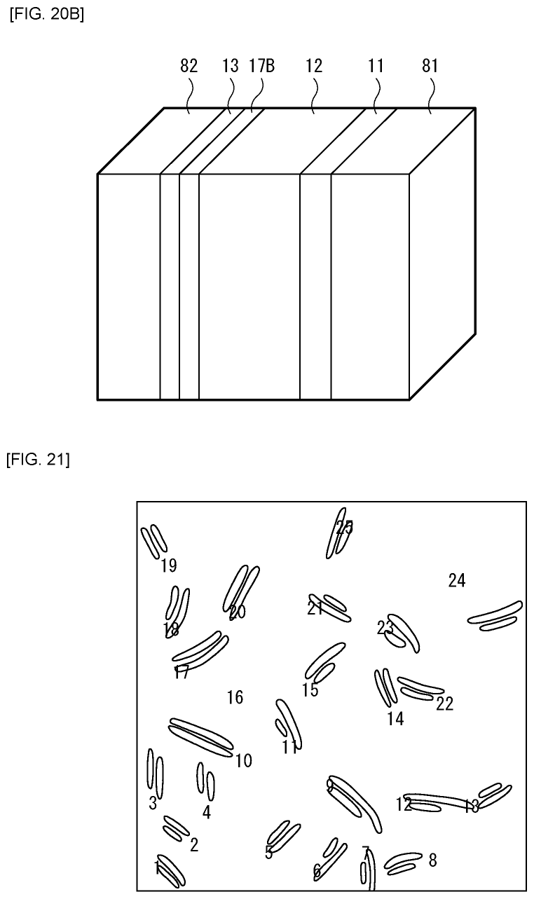

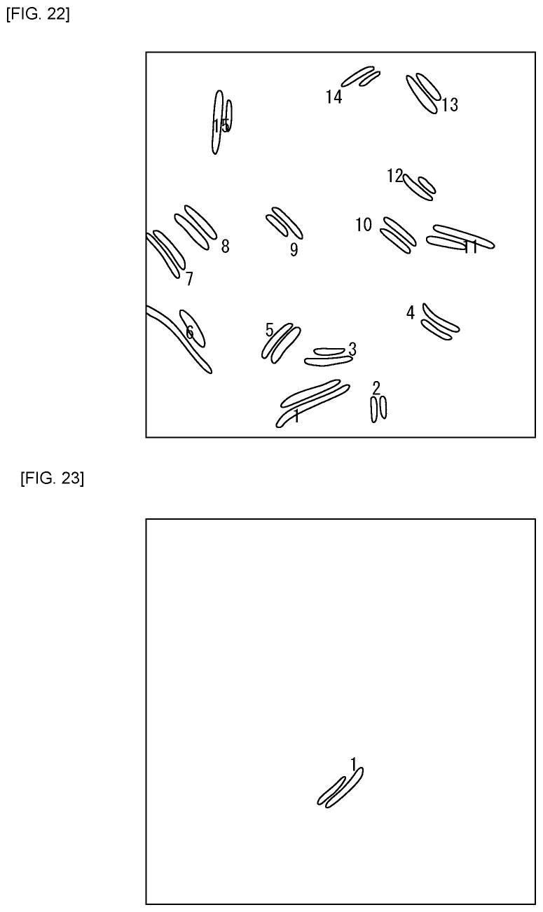

In Experiment Example 2 in which the substrate stage temperature (the film formation substrate temperature) in a case where an organic photoelectric conversion layer was formed was 26° C., fifteen lattice fringes were confirmed in a square plane of the organic photoelectric conversion layer having a side of 100 nm as illustrated in FIG. 22. The domain density (ρ) of the plane of the organic photoelectric conversion layer in Experiment Example 2 was about 1500 (domains/square μm). In addition, Experiment Example 2 offered a favorable result: an afterimage characteristic of 3.4 ms and an EQE of 79.8%. In contrast, in Experiment Example 1 in which the film formation substrate temperature in a case where an organic photoelectric conversion layer was formed was 40° C., 25 lattice fringes were confirmed in a square plane of the organic photoelectric conversion layer having a side of 100 nm as illustrated in FIG. 21. The domain density (ρ) of the plane of the organic photoelectric conversion layer in Experiment Example 1 was about 2500 (domains/square μm). In addition, Experiment Example 1 offered an afterimage characteristic of 1.2 ms and an EQE of 80.6%. This was a more favorable result than that of Experiment Example 2. In contrast, in Experiment Example 3 in which the film formation substrate temperature in a case where an organic photoelectric conversion layer was formed was 0° C., one lattice fringe was confirmed in a square plane of the organic photoelectric conversion layer having a side of 100 nm as illustrated in FIG. 23. The domain density (ρ) of the plane of the organic photoelectric conversion layer in Experiment Example 1 was 100 (domains/square μm) or less. In addition, Experiment Example 3 offered an afterimage characteristic of 7.8 ms and an EQE of 62.3%. Both the afterimage characteristics and the EQE were more unfavorable than those of Experiment Example 2.

In addition, TEM analysis was carried out on a sample of Experiment Example 1 by forming a carbon protective film 82 on the upper electrode 13 as illustrated in FIG. 20A, then rotating it by 90° C. as illustrated in FIG. 20B, and fabricating a thin sample of the organic photoelectric conversion layer 12 near the lower electrode 11 side and the upper electrode 13 side as in the TEM analysis described above.

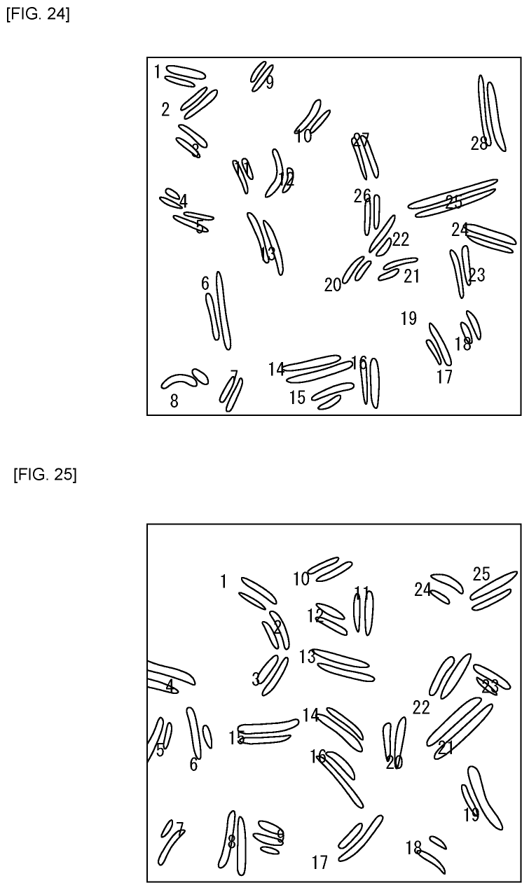

FIG. 24 schematically illustrates a TEM image of the organic photoelectric conversion layer 12 in Experiment Example 1 near the lower electrode 11 side in the planar direction. FIG. 25 schematically illustrates a TEM image of the organic photoelectric conversion layer 12 in Experiment Example 1 near the upper electrode 13 side in the planar direction. 28 domains were confirmable near the lower electrode 11 side and 25 domains were confirmable near the upper electrode 13 side. The difference falls within the range (±√N) of the statistical error described above. It can be said that the organic photoelectric conversion layer 12 has substantially the same areal density of domains at any positions in the film thickness direction.

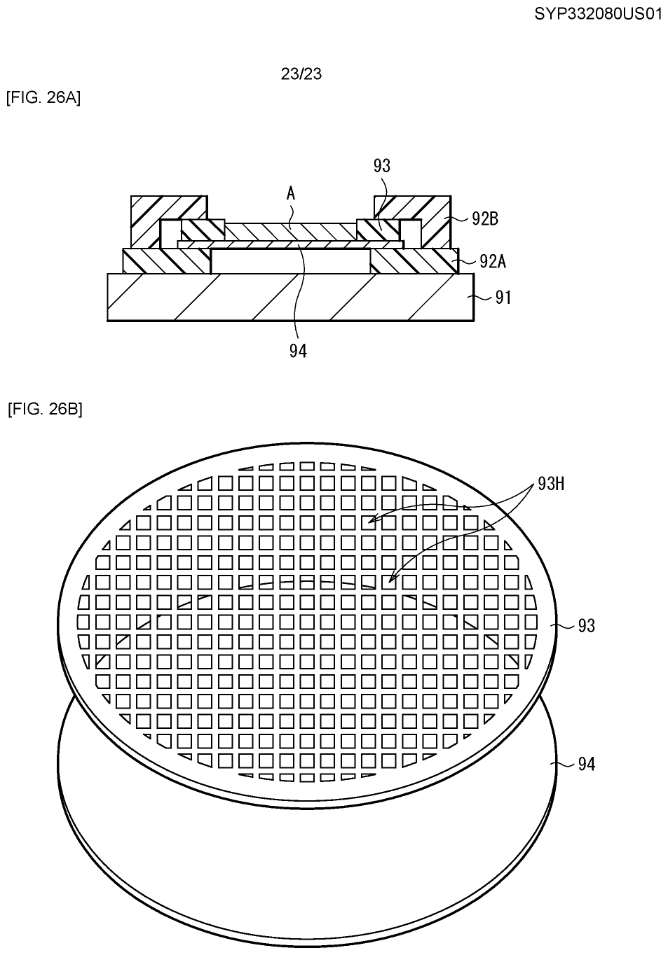

It is to be noted that a deposited film A also offers a similar effect under the same film formation condition as the internal structure of the organic photoelectric conversion layer 12. The deposited film A is formed by co-deposition on a hole 93H section of a grid 93. The grid 93 is fixed onto a quartz substrate 91 by Kapton tapes 92A and 92B, for example, as illustrated in FIG. 26A. This seems to be because the speed is limited by molecule diffusion on the surface before the deposition of the next molecules during deposition. As illustrated in FIG. 26B, the plurality of holes 93H is formed on the surface of a copper plate, for example, in the shape of a lattice as the grid 93. The copper plate has, for example, a circular shape. The bottom surface of the grid 93 is provided, for example, with a carbon film and a support film as a support film 94. A deposited film (the organic photoelectric conversion layer 12) is formed on this support film 94. The carbon film has a minute hole. The support film covers the minute hole of the carbon film.

As described above, it has been found that it is possible to obtain favorable afterimage characteristics and EQE by forming domains in a horizontal cross section of an organic photoelectric conversion layer and causing the areal density of domains to be substantially the same at any positions in the film thickness direction. Further, it has been found that it is possible to obtain more favorable afterimage characteristics and EQE by increasing the areal density of domains in the organic photoelectric conversion layer.

Description has been given above with reference to the embodiment, the modification examples 1 and 2, and the working examples, but the content of the present disclosure is not limited to the embodiment or the like described above. Various modifications are possible. For example, in the embodiment described above, the photoelectric conversion element has a configuration in which the organic photoelectric conversion section 10 that detects green light and the inorganic photoelectric conversion section 32B and the inorganic photoelectric conversion section 32R that respectively detect blue light and red light are stacked. However, the content of the present disclosure is not limited to such a structure. In other words, the content of the present disclosure is not limited to the visible light, but the organic photoelectric conversion section may detect the red light or the blue light or the inorganic photoelectric conversion sections may detect the green light.

In addition, the number of these organic photoelectric conversion sections and inorganic photoelectric conversion sections or the proportion thereof is not limited. The two or more organic photoelectric conversion sections may be provided or color signals of a plurality of colors may be obtained with the organic photoelectric conversion section alone. Further, a structure is not limited to the structure in which the organic photoelectric conversion section and the inorganic photoelectric conversion sections are stacked in the vertical direction, but the organic photoelectric conversion section and the inorganic photoelectric conversion sections may be placed side by side along a substrate surface.

Moreover, the embodiment or the like described above exemplifies the configuration of the back-illuminated imaging device, but the content of the present disclosure is also applicable to a front-illuminated imaging device. In addition, the photoelectric conversion element according to the present disclosure does not necessarily have to include all of the components described in the embodiment above and may include another layer on the contrary.

It is to be noted that the effects described herein are merely examples, but not limitative. In addition, there may be other effects.

It is to be noted that the present technology may also have configurations as follows. The present technology having the following configurations forms an organic photoelectric conversion layer including at least one or more domains in a horizontal cross section. Each of the one or more domains is formed by using one organic semiconductor material. This increases the probability that excitons generated in the organic photoelectric conversion layer irradiated with light move to the first electrode and the second electrode. This allows both high external quantum efficiency and favorable afterimage characteristics to be achieved.

(1)

A photoelectric conversion element including:

a first electrode;

a second electrode that is disposed to be opposed to the first electrode; and

an organic photoelectric conversion layer that is provided between the first electrode and the second electrode and includes one organic semiconductor material, the organic photoelectric conversion layer including at least one or more domains in a horizontal cross section, the one or more domains being each formed by using the one organic semiconductor material.

(2)

The photoelectric conversion element according to (1), in which the organic photoelectric conversion layer has substantially same areal density of the domains at any positions in a film thickness direction.

(3)

The photoelectric conversion element according to (1) or (2), in which the one organic semiconductor material forms domains at least a portion of which has a percolation structure in the organic photoelectric conversion layer, the organic photoelectric conversion layer having an areal density of 1500 domains/square micron or more.

(4)

The photoelectric conversion element according to any one of (1) to (3), in which each of the domains is partially in contact with the first electrode or the second electrode.

(5)

The photoelectric conversion element according to any one of (1) to (4), in which each of the domains is partially in contact with the first electrode and the second electrode.

(6)

The photoelectric conversion element according to any one of (1) to (5), further including a buffer layer between at least one of the first electrode or the second electrode and the organic photoelectric conversion layer.

(7)

The photoelectric conversion element according to any one of (1) to (6), in which at least a portion of the domains has crystallizability.

(8)

The photoelectric conversion element according to any one of (1) to (7), in which each of the domains includes a crystal of the one organic semiconductor material.

(9)

The photoelectric conversion element according to (8), in which a planar projected area ratio of the crystal is 0.5 or less, the planar projected area ratio being obtained by projecting the organic photoelectric conversion layer in a film thickness direction.

(10)

The photoelectric conversion element according to any one of (1) to (9), in which the organic photoelectric conversion layer includes the one organic semiconductor material and another organic semiconductor material having a different electrical conduction type from an electrical conduction type of the one organic semiconductor material, the organic photoelectric conversion layer having a bulk hetero structure in a portion of a layer.

(11)

An imaging device including

pixels each including one or more organic photoelectric conversion sections, in which

the organic photoelectric conversion sections each include
a first electrode,
a second electrode that is disposed to be opposed to the first electrode, and
an organic photoelectric conversion layer that is provided between the first electrode and the second electrode and includes one organic semiconductor material, the organic photoelectric conversion layer including at least one or more domains in a horizontal cross section, the one or more domains being each formed by using the one organic semiconductor material.
   (12)

The imaging device according to (11), in which the one or more organic photoelectric conversion sections and one or more inorganic photoelectric conversion sections are stacked in each of the pixels, the one or more inorganic photoelectric conversion sections each performing photoelectric conversion in a wavelength region different from wavelength regions of the organic photoelectric conversion sections.

(13)

The imaging device according to (12), in which

each of the inorganic photoelectric conversion sections is formed to be embedded in a semiconductor substrate, and

each of the organic photoelectric conversion sections is formed on a first surface side of the semiconductor substrate.

(14)

The imaging device according to (13), in which a multilayer wiring layer is formed on a second surface side of the semiconductor substrate.

(15)

The imaging device according to (13) or (14), in which

each of the organic photoelectric conversion sections photoelectrically converts green light, and

an inorganic photoelectric conversion section that photoelectrically converts blue light and an inorganic photoelectric conversion section that photoelectrically converts red light are stacked in the semiconductor substrate.

(16)

The imaging device according to any one of (11) to (15), in which a plurality of the organic photoelectric conversion sections is stacked in each of the pixels, the plurality of the organic photoelectric conversion sections performing photoelectric conversion in respective wavelength regions different from each other.

This application claims the priority on the basis of Japanese Patent Application No. 2019-093702 filed with Japan Patent Office on May 17, 2019, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode;
a second electrode that is disposed to be opposed to the first electrode; and
an organic photoelectric conversion layer that is provided between the first electrode and the second electrode and includes one organic semiconductor material, the organic photoelectric conversion layer including at least one or more domains in a horizontal cross section, the one or more domains being each formed by using the one organic semiconductor material.

2. The photoelectric conversion element according to claim 1, wherein the organic photoelectric conversion layer has substantially same areal density of the domains at any positions in a film thickness direction.

3. The photoelectric conversion element according to claim 1, wherein the one organic semiconductor material forms domains at least a portion of which has a percolation structure in the organic photoelectric conversion layer, the organic photoelectric conversion layer having an areal density of 1500 domains/square micron or more.

4. The photoelectric conversion element according to claim 1, wherein each of the domains is partially in contact with the first electrode or the second electrode.

5. The photoelectric conversion element according to claim 1, wherein each of the domains is partially in contact with the first electrode and the second electrode.

6. The photoelectric conversion element according to claim 1, further comprising a buffer layer between at least one of the first electrode or the second electrode and the organic photoelectric conversion layer.

7. The photoelectric conversion element according to claim 1, wherein at least a portion of the domains has crystallizability.

8. The photoelectric conversion element according to claim 1, wherein each of the domains includes a crystal of the one organic semiconductor material.

9. The photoelectric conversion element according to claim 8, wherein a planar projected area ratio of the crystal is 0.5 or less, the planar projected area ratio being obtained by projecting the organic photoelectric conversion layer in a film thickness direction.

10. The photoelectric conversion element according to claim 1, wherein the organic photoelectric conversion layer includes the one organic semiconductor material and another organic semiconductor material having a different electrical conduction type from an electrical conduction type of the one organic semiconductor material, the organic photoelectric conversion layer having a bulk heterostructure in a portion of a layer.

11. An imaging device comprising
pixels each including one or more organic photoelectric conversion sections, wherein
the organic photoelectric conversion sections each include
a first electrode,
a second electrode that is disposed to be opposed to the first electrode, and
an organic photoelectric conversion layer that is provided between the first electrode and the second electrode and includes one organic semiconductor material, the organic photoelectric conversion layer including at least one or more domains in a horizontal cross section, the one or more domains being each formed by using the one organic semiconductor material.

12. The imaging device according to claim 11, wherein the one or more organic photoelectric conversion sections and one or more inorganic photoelectric conversion sections are stacked in each of the pixels, the one or more inorganic photoelectric conversion sections each performing photoelectric conversion in a wavelength region different from wavelength regions of the organic photoelectric conversion sections.

13. The imaging device according to claim 12, wherein
each of the inorganic photoelectric conversion sections is formed to be embedded in a semiconductor substrate, and
each of the organic photoelectric conversion sections is formed on a first surface side of the semiconductor substrate.

14. The imaging device according to claim 13, wherein a multilayer wiring layer is formed on a second surface side of the semiconductor substrate.

15. The imaging device according to claim 13, wherein
each of the organic photoelectric conversion sections photoelectrically converts green light, and
an inorganic photoelectric conversion section that photoelectrically converts blue light and an inorganic photoelectric conversion section that photoelectrically converts red light are stacked in the semiconductor substrate.

16. The imaging device according to claim 11, wherein a plurality of the organic photoelectric conversion sections is stacked in each of the pixels, the plurality of the organic photoelectric conversion sections performing photoelectric conversion in respective wavelength regions different from each other.
